(19) United States
(12) Patent Application Publication
(10) Pub. No.: US 2018/0182452 A1
(43) Pub. Date: Jun. 28, 2018

(54) MEMORY SYSTEM AND OPERATING METHOD OF MEMORY SYSTEM

(71) Applicant: SK hynix Inc., Gyeonggi-do (KR)

(72) Inventor: Dong-Sop LEE, Gyeonggi-do (KR)

(21) Appl. No.: 15/824,572

(22) Filed: Nov. 28, 2017

(30) Foreign Application Priority Data
Dec. 23, 2016 (KR) 10-2016-0177915

(51) Int. Cl. G11C 11/56; G11C 16/30; G11C 5/06; G11C 5/14

(52) U.S. Cl. CPC G11C 11/5621; G11C 16/30; G06F 1/3275; G11C 5/147; G11C 5/063

(57) ABSTRACT

a memory system may include: a memory device including a plurality of memory dies and suitable for performing, in the plurality of memory dies, command operations; and a controller suitable for: dividing sub-jobs of a command job corresponding to the command operations on a logical unit size basis; queuing the divided sub-jobs; and performing the queued sub-jobs to the memory dies with variable operating energy levels and operating clocks. The controller may monitor a status and a job load for at least one queued sub-job while performing the at least one queued sub-job to the memory dies, and interactively and dynamically adjusts an energy level and an operating clock for the at least one queued sub-job according to a result of the monitoring.

### CROSS-REFERENCE TO RELATED APPLICATION

This application claims priority under 35 U.S.C. § 119 to Korean Patent Application No. 10-2016-0177915 filed on Dec. 23, 2016 in the Korean Intellectual Property Office, the disclosure of which is herein incorporated by reference in its entirety.

### TECHNICAL FIELD

Exemplary embodiments relate to a memory system, and more particularly, to a memory system for processing data to and from a memory device, and an operating method thereof.

### DISCUSSION OF THE RELATED ART

The computer environment paradigm has changed to ubiquitous computing systems that can be used anytime and anywhere. Due to this, use of portable electronic devices such as mobile phones, digital cameras, and notebook computers has rapidly increased. These portable electronic devices generally use a memory system having one or more memory devices for storing data. A memory system may be used as a main memory device or an auxiliary memory device of a portable electronic device.

Memory systems provide excellent stability, durability, high information access speed, and low power consumption because they have no moving parts. Examples of memory systems having such advantages include universal serial bus (USB) memory devices, memory cards having various interfaces, and solid state drives (SSD).

### SUMMARY

Various embodiments are directed to a memory system capable of maximizing use efficiency in use of a memory device, and an operating method thereof.

In an embodiment, a memory system may include: a memory device including a plurality of memory dies and suitable for performing, in the plurality of memory dies, command operations; and a controller suitable for: dividing sub-jobs of a command job corresponding to the command operations on a logical unit size basis; queuing the divided sub-jobs; and performing the queued sub-jobs to the memory dies with variable operating energy levels and operating clocks The controller may monitor a status and a job load for at least one queued sub-job while performing the at least one queued sub-job to the memory dies, and interactively and dynamically adjusts an energy level and an operating clock for the at least one queued sub-job according to a result of the monitoring.

The controller may perform a plurality of first sub-jobs of the queuing sub-jobs in a first operating energy level and a first operating clock, and then performs pending first sub-jobs of the queuing sub-jobs in the third operating energy level and the third operating clock, and the controller may perform and a plurality of second sub-jobs of the queuing sub-jobs in a second operating energy level and a second operating clock, and then may perform pending second sub-jobs of the queuing sub-jobs in a fourth operating energy level and a fourth operating clock.

The controller may monitor a first status and a first job load corresponding to the performing of the first sub-jobs, in the first operating energy level and the first operating clock, and the controller may monitor a second status and a second job load corresponding to the performing of the second sub-jobs, in the second operating energy level and the second operating clock.

The controller may determine the third operating energy level and the third operating clock, through scale up or down for the first operating energy level and the first operating clock, in correspondence with the first status and the first job load, and the controller may determine the fourth operating energy level and the fourth operating clock, through scale up or down for the second operating energy level and the second operating clock, in correspondence with the second status and the second job load.

In the case where the pending second sub-jobs are last sub-jobs of the queuing sub-jobs, the controller may determine the fourth operating clock as a minimum clock, through scale down for the second operating clock, and then may determine the fourth operating energy level, through scale up or down for the second operating energy level, in correspondence with the fourth operating clock that is the minimum clock.

The controller may control one or more of energy level and operating clock for sub-jobs having a minimum performance and a maximum latency or sub-jobs requiring a maximum performance among the queued sub-jobs such that the energy level is a maximum energy level and the operating clock is a maximum operating clock.

In the case where a temperature in the memory device and the controller is equal to or greater than a threshold temperature, the controller may scale down the energy level and the operating clock for the at least one queued sub-job.

In the case where a temperature in the memory device and the controller is lover than a threshold temperature the controller may scale up or down the energy level and the operating clock for the at least one queued sub-job.

In the case where performance and latency of the at least one queued sub-job is maintained in the same status for a predetermined time, the controller may scale down the energy level and scales up the operating clock for the at least one queued sub-job.

The status may include temperatures, performances and latencies of the controller and the memory device, and the job load may include pending sub-jobs of the queued sub-jobs.

The controller may include: a job parsing module suitable for parsing the command job; a sub-job queuing module suitable for queuing the sub-jobs corresponding to the parsed command job on the logical unit size basis; sub-job modules suitable for respectively performing the queued sub-jobs to corresponding the memory dies; a monitor suitable for monitoring temperatures, performances and latencies in the controller and the memory device while the sub-job modules respectively perform the queued sub-jobs; and a power management control module suitable for checking a monitoring flag for the parsed command job, the queued sub-jobs, the temperatures, the performances and the latencies, and then adjusting one or more of the operating energy levels and the operating clocks of the respective sub-job modules.

The power manage control module may include: control units suitable for controlling one or more of the operating energy levels and the operating clocks of the respective sub-job modules according to the parsed command job, the queued sub-jobs, and the monitoring flag; and drive units suitable for providing the controlled operating energy levels and/or the controlled operating clocks to the respective sub-job modules.

In an embodiment, a method for operating a memory system which includes a memory device including a plurality of memory dies, the method may include: dividing sub-jobs of a command job corresponding to the command operations on a logical unit size basis; queuing the divided sub-jobs; performing the queued sub-jobs to the memory dies with variable operating energy levels and operating clocks; monitoring statuses and job loads of the queued sub-jobs during the performing of the queued sub-jobs; and interactively and dynamically controlling one or more of the energy levels and the operating clocks through scale up or scale down according to a result of the monitoring. The statuses may include temperatures, performances and latencies in the memory device and a controller of the memory device, and the job loads may include pending sub-jobs of the queued sub-jobs.

The performing may include performing first sub-jobs of the queuing sub-jobs in a first operating energy level and a first operating clock, and then performing pending first sub-jobs of the queuing sub-jobs in a third operating energy level and a third operating clock; and performing second sub-jobs of the queuing sub-jobs in a second operating energy level and a second operating clock, and then performing pending second sub-jobs of the queuing sub-jobs in a fourth operating energy level and a fourth operating clock, and the monitoring may include: monitoring a first status and a first job load corresponding to the performing of the first sub-jobs, in the first operating energy level and the first operating clock; and monitoring a second status and a second job load corresponding to the performing of the second sub-jobs, in the second operating energy level and the second operating clock.

The controlling may include: determining the third operating energy level and the third operating clock, through scale up or down for the first operating energy level and the first operating clock, in correspondence with the first status and the first job load; and determining the fourth operating energy level and the fourth operating clock, through scale up or down for the second operating energy level and the second operating clock, in correspondence with the second status and the second job load.

The controlling of one or more of the energy levels and the operating clocks may include controlling one or more of energy level and operating clock for last sub-jobs of the queued sub-jobs such that the operating clock is a minimum operating clock and the energy level corresponds to the minimum operating clock.

The controlling of one or more of the energy levels and the operating clocks may include controlling one or more of energy level and operating clock for sub-jobs having a minimum performance and a maximum latency or sub-jobs requiring a maximum performance among the queued sub-jobs such that the energy level is a maximum energy level and the operating clock is a maximum operating clock.

In the case where temperatures in the memory device and the controller are equal to or greater than a threshold temperature, the controlling of one or more of the energy levels and the operating clocks may include scaling down one or more of the energy levels and the operating clocks for the queued sub-jobs.

In the case where the temperatures in the memory device and the controller are lower than the threshold temperature, the controlling of one or more of the energy levels and the operating clocks may include scaling up one or more of the energy levels and the operating clocks for the queued sub-jobs.

In the case where performance and latency of the first sub-jobs are maintained in the same statuses for a predetermined time, the controlling of one or more of the energy levels and the operating clocks may include scaling down the energy levels and scaling up the operating clocks for the queued sub-jobs.

In an embodiment, a memory system may include: a job parsing module configured to parse a command job for command operations corresponding to a plurality of commands received from a host; sub-job modules configured to respectively perform sub-jobs corresponding to the parsed command job in memory dies included in a memory device; and a power management control module configured to dynamically control operating energy levels in the sub-job modules, in the case where the sub-job modules respectively perform the corresponding sub-jobs.

The memory system may further include a monitor configured to monitor a temperature in the memory system including the memory device and performances and latencies in the sub-job modules when the sub-jobs are performed in the memory dies.

The power management control module may dynamically control the respective operating energy levels by the sub-job modules, through scale up or down corresponding the temperature, the performances and the latencies, in all energy levels allowed to be used in the memory system.

In an embodiment, a memory system may include: a job parsing module configured to parse a command job for command operations corresponding to a plurality of commands received from a host; sub-job modules configured to respectively perform sub-jobs corresponding to the parsed command job in memory dies included in a memory device; and a power management control module configured to dynamically control operating clocks in the sub-job modules, in the case where the sub-job modules respectively perform the corresponding sub-jobs.

The memory system may further include a monitor configured to monitor a temperature in the memory system including the memory device and performances and latencies in the sub-job modules when the sub-jobs are performed in the memory dies.

The power management control module may dynamically control the operating clocks by the sub-job modules through scale up or down for reference clock of the memory system, in correspondence with the temperature the performances, and the latencies.

### BRIEF DESCRIPTION OF THE DRAWINGS

These and other features and advantages of the present invention will become apparent to those skilled in the art to which the present invention pertains from the following detailed description in reference to the accompanying drawings, wherein:

FIG. 1 is a block diagram illustrating a data processing system including a memory system in accordance with an embodiment of the present invention.

FIG. 2 is a schematic diagram illustrating an exemplary configuration of a memory device employed in the memory system shown in FIG. 1.

FIG. 3 is a circuit diagram illustrating an exemplary configuration of a memory cell array of a memory block in the memory device shown in FIG. 2.

FIG. 4 is a schematic diagram illustrating an exemplary three-dimensional structure of the memory device shown in FIG. 2.

FIGS. 5 to 7 are diagrams schematically illustrating more detail of the memory system shown in FIGS. 1 to 4 and an operation of the memory system, in accordance with an embodiment of the present invention.

FIG. 8 is a flowchart illustrating an operation of the memory system shown in FIGS. 1 to 7, in accordance with an embodiment of the present invention.

FIGS. 9 to 17 are diagrams schematically illustrating application examples of the data processing system shown in FIGS. 1 to 7 in accordance with various embodiments of the present invention.

### DETAILED DESCRIPTION

Various embodiments of the present invention are described below in more detail with reference to the accompanying drawings. We note, however, that the present invention may be embodied in different other embodiments, forms and variations thereof and should not be construed as being limited to the embodiments set forth herein. Rather, the described embodiments are provided so that this disclosure will be thorough and complete, and will fully convey the present invention to those skilled in the art to which this invention pertains. Throughout the disclosure, like reference numerals refer to like parts throughout the various figures and embodiments of the present invention.

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present invention.

The drawings are not necessarily to scale and, in some instances, proportions may have been exaggerated in order to dearly illustrate features of the embodiments.

It will be further understood that when an element is referred to as being “connected to”, or “coupled to” another element, it may be directly on, connected to, or coupled to the other element, or one or more intervening elements may be present. In addition, it will also be understood that when an element is referred to as being “between” two elements, it may be the only element between the two elements or one or more intervening elements may also be present.

The terminology used herein is for the purpose of describing particular embodiments only and is not intended to be is limiting of the present invention. As used herein, singular forms are intended to include the plural forms as well, unless the context clearly indicates otherwise. It will be further understood that the terms “comprises,” “comprising,” “includes,” and “including” when used in this specification, specify the presence of the stated elements and do not preclude the presence or addition of one or more other elements. As used herein, the term “and/or” includes any and all combinations of one or more of the associated listed items.

Unless otherwise defined, all terms including technical and scientific terms used herein have the same meaning as commonly understood by one of ordinary skill in the art to which the present invention belongs in view of the present disclosure. It will be further understood that terms, such as those defined in commonly used dictionaries, should be interpreted as having a meaning that is consistent with their meaning in the context of the present disclosure and the relevant art and will not be interpreted in an idealized or overly formal sense unless expressly so defined herein.

In the following description, numerous specific details are set forth in order to provide a thorough understanding of the present invention. The present invention may be practiced without some or all of these specific details. In other instances, well-known process structures and/or processes have not been described in detail is in order not to unnecessarily obscure the present invention.

It is also noted, that in some instances, as would be apparent to those skilled in the relevant art, a feature or element described in connection with one embodiment may be used singly or in combination with other features or elements of another embodiment, unless otherwise specifically indicated.

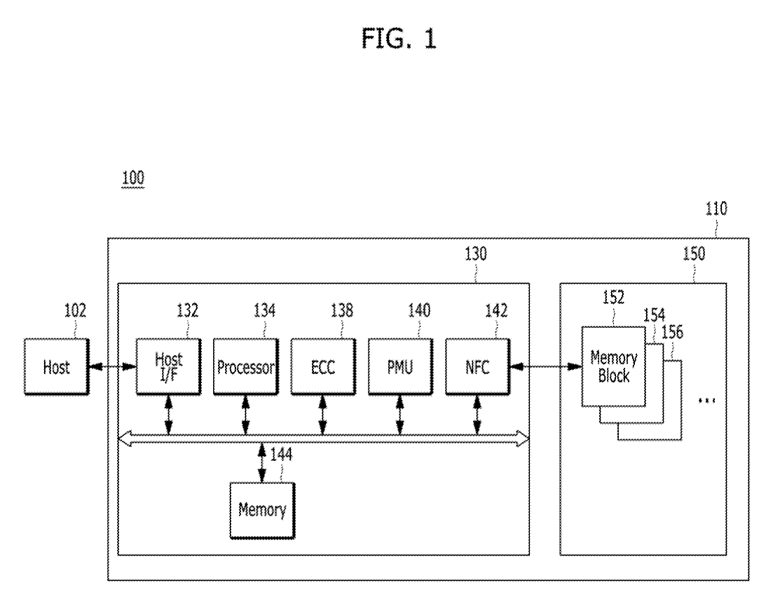

FIG. 1 is a block diagram illustrating a data processing system 100 including a memory system 110 in accordance with an embodiment of the present invention.

Referring to FIG. 1, the data processing system 100 may include a host 102 and the memory system 110.

The host 102 may include portable electronic devices such as a mobile phone, MP3 player and laptop computer or non-portable electronic devices such as a desktop computer, game machine, TV and projector.

The host 102 may include at least one OS (operating system), and the OS may manage and control overall functions and operations of the host 102, and provide an operation between the host 102 and a user using the data processing system 100 or the memory system 110. The OS may support functions and operations corresponding to the use purpose and usage of a user. For example, the OS may be divided into a general OS and a mobile OS, depending on the mobility of the host 102. The general OS may be divided into a personal OS and an enterprise OS, depending on the environment of a user. For example, the personal OS configured to support a function of providing a service to general users may include Windows and Chrome, and the enterprise OS configured to secure and support high performance may include Windows server, Linux and Unix. Furthermore, the mobile OS configured to support a function of providing a mobile service to users and a power saving function of a system may include Android, iOS and Windows Mobile. For example, the host 102 may include a plurality of OSs, and execute an OS to perform an operation corresponding to a user's request on the memory system 110.

The memory system 110 may operate to store data for the host 102 in response to a request of the host 102. Non-limited examples of the memory system 110 may include a solid state drive (SSD), a multi-media card (MMC), a secure digital (SD) card, a universal storage bus (USB) device, a universal flash storage (UFS) device, compact flash (CF) card, a smart media card (SMC), a personal computer memory card international association (PCMCIA) card and memory stick. The MMC may include an embedded MMC (eMMC), reduced size MMC (RS-MMC) and micro-MMC. The SD card may include a mini-SD card and micro-SD card.

The memory system 110 may be embodied by various types of storage devices. Non-limited examples of storage devices included in the memory system 110 may include volatile memory devices such as a DRAM dynamic random access memory (DRAM) and a static RAM (SRAM) and nonvolatile memory devices such as a read only memory (ROM), a mask ROM (MROM), a programmable ROM (PROM), an erasable programmable ROM (EPROM), an electrically erasable programmable ROM (EEPROM), a ferroelectric RAM (FRAM), a phase-change RAM (PRAM), a magneto-resistive RAM (MRAM), resistive RAM (RRAM) and a flash memory. The flash memory may have a 3-dimensional (3D) stack structure.

The memory system 110 may include a memory device 150 and a controller 130. The memory device 150 may store data for the host 120 and the controller 130 may control data storage into the memory device 150.

The controller 130 and the memory device 150 may be integrated into a single semiconductor device, which may be included in the various types of memory systems as exemplified above.

Non-limited application examples of the memory system 110 may include a computer, an Ultra Mobile PC (UMPC), a workstation, a net-book, a Personal Digital Assistant (PDA), a portable computer, a web tablet, a tablet computer, a wireless phone, a mobile phone, a smart phone, an e-book, a Portable Multimedia Player (PMP), a portable game machine, a navigation system, a black box, a digital camera, a Digital Multimedia Broadcasting (DMB) player, a 3-dimensional television, a smart television, a digital audio recorder, a digital audio player, a digital picture recorder, a digital picture player, a digital video recorder, a digital video player, a storage device constituting a data center, a device capable of transmitting/receiving information in a wireless environment, one of various electronic devices constituting a home network, one of various electronic devices constituting a computer network, one of various electronic devices constituting a telematics network, a Radio Frequency Identification (RFID) device, or one of various components constituting a computing system.

The memory device 150 may be a nonvolatile memory device and may retain data stored therein even though power is not supplied. The memory device 150 may store data provided from the host 102 through a write operation, and provide data stored therein to the host 102 through a read operation. The memory device 150 may include a plurality of memory dies (not shown), each memory die including a plurality of planes (not shown) each plane including a plurality of memory blocks 152 to 156, each of the memory blocks 152 to 156 may include a plurality of pages, and each of the pages may include a plurality of memory cells coupled to a word line.

The controller 130 may control the memory device 150 in response to a request from the host 102. For example, the controller 130 may provide data read from the memory device 150 to the host 102, and store data provided from the host 102 into the memory device 150. For this operation, the controller 130 may control read, write, program and erase operations of the memory device 150.

The controller 130 may include a host interface (I/F) unit 132, a processor 134, an error correction code (ECC) unit 138, a Power Management Unit (PMU) 140, a NAND flash controller (NFC) 142 and a memory 144 all operatively coupled via an internal bus.

The host interface unit 132 may be configured to process a command and data of the host 102, and may communicate with the host 102 through one or more of various interface protocols such as universal serial bus (USB), multi-media card (MMC), peripheral component interconnect-express (PCI-E), small computer system interface (SCSI), serial-attached SCSI (SAS), serial advanced technology attachment (SATA), parallel advanced technology attachment (PATA), enhanced small disk interface (ESDI) and integrated drive electronics (IDE).

The ECC unit 138 may detect and correct an error contained in the data read from the memory device 150. In other words, the ECC unit 138 may perform an error correction decoding process to the data read from the memory device 150 through an ECC code used during an ECC encoding process. According to a result of the error correction decoding process, the ECC unit 138 may output a signal, for example, an error correction success/fail signal. When the number of error bits is more than a threshold value of correctable error bits, the ECC unit 138 may not correct the error bits, and may output an error correction fail signal.

The ECC unit 138 may perform error correction through a coded modulation such as Low Density Parity Check (LDPC) code, Bose-Chaudhri-Hocquenghem (BCH) code, turbo code, Reed-Solomon code, convolution code, Recursive Systematic Code (RSC), Trellis-Coded Modulation (TCM) and Block coded modulation (BCM). However, the ECC unit 138 is not limited thereto. The ECC unit 138 may include all circuits, modules, systems or devices for error correction.

The PMU 140 may provide and manage power of the controller 130.

The NFC 142 may serve as a memory/storage interface for interfacing the controller 130 and the memory device 150 such that the controller 130 controls the memory device 150 in response to a request from the host 102. When the memory device 150 is a flash memory or specifically a NAND flash memory, the NFC 142 may generate a control signal for the memory device 150 and process data to be provided to the memory device 150 under the control of the processor 134. The NFC 142 may work as an interface (e.g., a NAND flash interface) for processing a command and data between the controller 130 and the memory device 150. Specifically, the NFC 142 may support data transfer between the controller 130 and the memory device 150.

The memory 144 may serve as a working memory of the memory system 110 and the controller 130, and store data for driving the memory system 110 and the controller 130. The controller 130 may control the memory device 150 to perform read, write, program, and erase operations in response to a request from the host 102. The controller 130 may provide data read from the memory device 150 to the host 102, may store data provided from the host 102 into the memory device 150. The memory 144 may store data required for the controller 130 and the memory device 150 to perform these operations.

The memory 144 may be embodied by a volatile memory. For example, the memory 144 may be embodied by static random access memory (SRAM) or dynamic random access memory (DRAM). The memory 144 may be disposed within or out of the controller 130. FIG. 1 exemplifies the memory 144 disposed within the controller 130. In an embodiment, the memory 144 may be embodied by an external volatile memory having a memory interface transferring data between the memory 144 and the controller 130.

The processor 134 may control the overall operations of the memory system 110. The processor 134 may drive firmware to control the overall operations of the memory system 110. The firmware may be referred to as flash translation layer (FTL).

The processor 134 of the controller 130 may include a management unit (not illustrated) for performing a bad management operation of the memory device 150. The management unit may perform a bad block management operation of checking a bad block, in which a program fail occurs due to the characteristic of a NAND flash memory during a program operation, among the plurality of memory blocks 152 to 156 included in the memory device 150. The management unit may write the program-failed data of the bad block to a new memory block. In the memory device 150 having a 3D stack structure, the bad block management operation may reduce the use efficiency of the memory device 150 and the reliability of the memory system 110. Thus, the bad block management operation needs to be performed with more reliability.

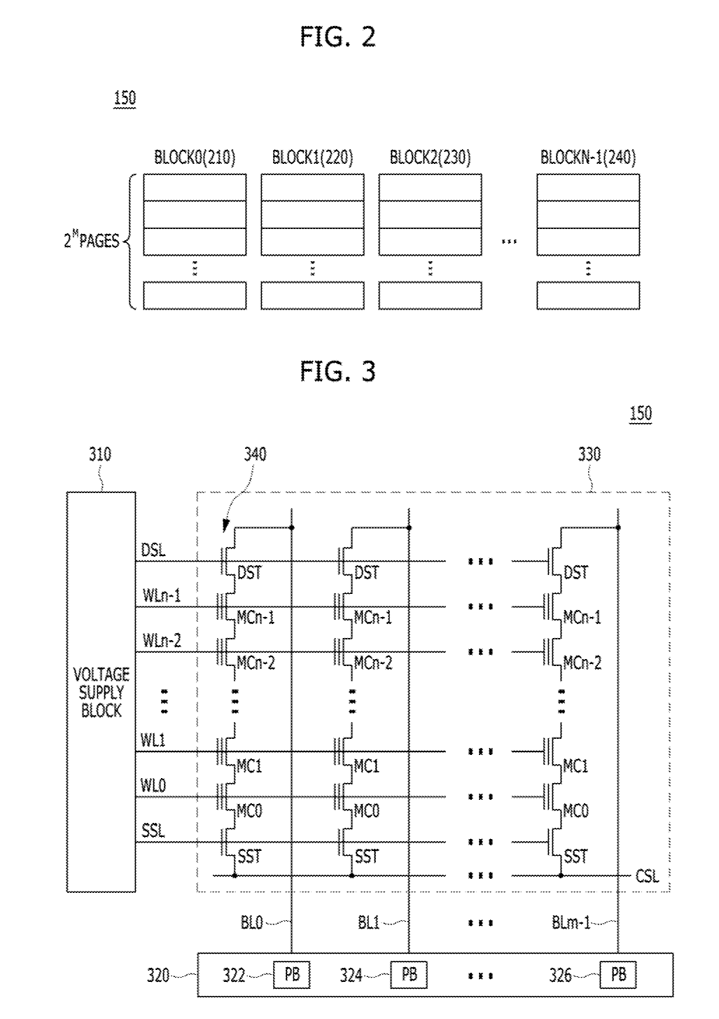

FIG. 2 is a schematic diagram illustrating the memory device 150 shown in FIG. 1.

Referring to FIG. 2, the memory device 150 may include a plurality of memory blocks 0 to N-1 and each of the blocks 0 to N-1 may include a plurality of pages, for example 2^{M} pages, the number of which may vary according to circuit design. Memory cells included in the respective memory blocks 0 to N-1 may be one or more of a single level cell (SLC) storing 1-bit data, or a multi-level cell (MLC) storing 2- or more- bit data, including a triple level cell (TLC) storing 3-bit data, a quadruple level cell (QLC) storing 4-bit level cell and so forth.

FIG. 3 is a circuit diagram illustrating an exemplary configuration of a memory cell array of a memory block in the memory device 150.

Referring to FIG. 3, a memory block 330 which may correspond to any of the plurality of memory blocks 152 to 156 included in the memory device 150 of the memory system 110 may include a plurality of cell strings 340 coupled to a plurality of corresponding bit lines BL0 to BLm-1. The cell string 340 of each column may include one or more drain select transistors DST and one or more source select transistors SST. Between the drain and source select transistors DST and SST, a plurality of memory cells MC0 to MCn-1 may be coupled in series. In an embodiment, each of the memory cell transistors MC0 to MCn-1 may be embodied by an MLC capable of storing data information of a plurality of bits. Each of the cell strings 340 may be electrically coupled to a corresponding bit line among the plurality of bit lines BL0 to BLm-1. For example, as illustrated in FIG. 3, the first cell string is coupled to the first bit line BL0, and the last cell string is coupled to the last bit line BLm-1.

Although FIG. 3 illustrates NAND flash memory cells, the invention is not limited in this way. It is noted that the memory cells may be NOR flash memory cells, or hybrid flash memory cells including two or more kinds of memory cells combined therein. Also, it is noted that the memory device 150 may be a flash memory device including a conductive floating gate as a charge storage layer or a charge trap flash (CTF) memory device including an insulation layer as a charge storage layer.

The memory device 150 may further include a voltage supply unit 310 which provides word line voltages including a program voltage, a read voltage and a pass voltage to supply to the word lines according to an operation mode. The voltage generation operation of the voltage supply unit 310 may be controlled by a control circuit (not illustrated). Under the control of the control circuit, the voltage supply unit 310 may select one of the memory blocks (or sectors) of the memory cell array, select one of the word lines of the selected memory block, and provide the word line voltages to the selected word line and the unselected word lines as may be needed.

The memory device 150 may include a read/write circuit 320 which is controlled by the control circuit. During a verification/normal read operation, the read/write circuit 320 may operate as a sense amplifier for reading data from the memory cell array. During a program operation, the read/write circuit 320 may operate as a write driver for driving bit lines according to data to be stored in the memory cell array. During a program operation, the read/write circuit 320 may receive from a buffer (not illustrated) data to be stored into the memory cell array, and drive bit lines according to the received data. The read/write circuit 320 may include a plurality of page buffers 322 to 326 respectively corresponding to columns (or bit lines) or column pairs (or bit line pairs), and each of the page buffers 322 to 326 may include a plurality of latches (not illustrated).

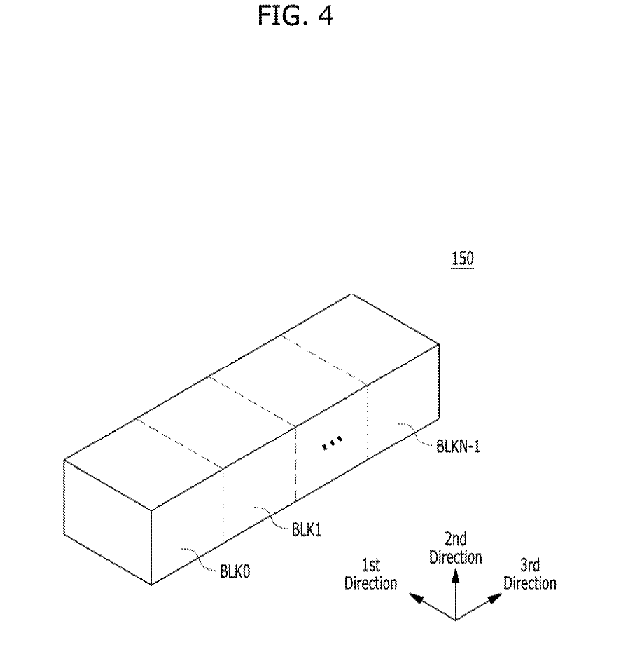

FIG. 4 is a schematic diagram illustrating an exemplary 3D structure of the memory device 150.

The memory device 150 may be implemented by a 2D or 3D memory device. For example, as illustrated in FIG. 4, the memory device 150 may be embodied by a nonvolatile memory device having a 3D stack structure. When the memory device 150 has a 3D structure, the memory device 150 may include a plurality of memory blocks BLK0 to BLKN-1 each having a 3D structure (or vertical structure).

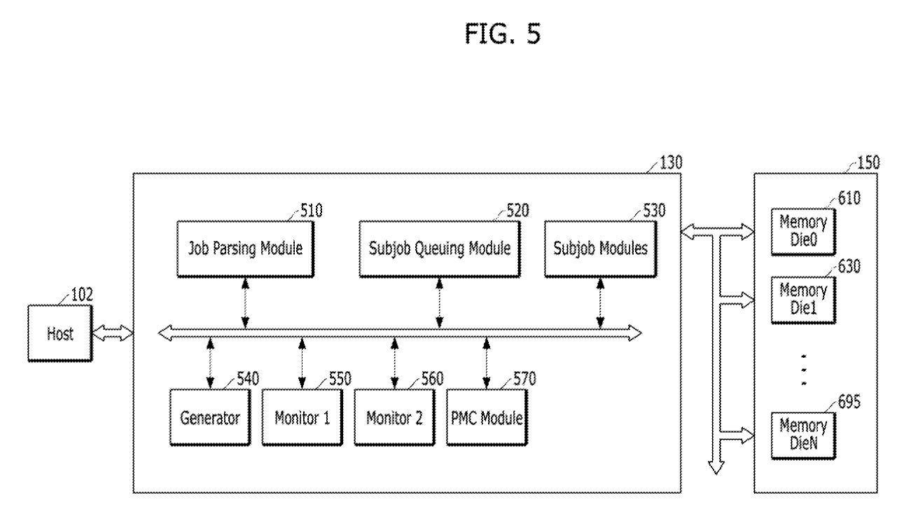

Hereinbelow detailed description will be made with reference to FIGS. 5 to 8, for data processing with respect to a memory device in a memory system in accordance with an embodiment, particularly, an operation of dynamically controlling operating parameters corresponding to a command operation and a background operation while the command operation and the background operation corresponding to a command received from a host 102 are performed.

FIGS. 5 to 7 are diagrams schematically illustrating more detail of the memory system 110 and an operation of the memory system 110. More specifically, FIGS. 5 to 7 are diagrams schematically illustrating an exemplary operation for controlling one or more operating parameters when a command operation is performed in a memory system in accordance with an embodiment of the present invention. In the described embodiment, for the sake of convenience as an example, a description is provided of an operation for dynamically controlling operating parameters corresponding to command operations in the case where the memory system 110 performs the command operations corresponding to commands received from the host 102. For example, the command operations may be program operations corresponding to write commands received from the host 102, read operations corresponding to read commands received from the host 102, or erase commands corresponding to erase commands received from the host 102. For the sake of convenience, description of the features of the memory system 110 which have already been described with reference to FIG. 1 is not repeated herein.

In an embodiment, when one or more command operations corresponding to commands received from the host 102 are being performed, job loads in and/or statuses of the controller 130 and the memory device 150 that correspond to the command operations are checked. Thereafter, one or more operating parameters which are used when the command operations are performed in the controller 130 and the memory device 150 are dynamically controlled in correspondence with the checked job loads and statuses. Furthermore, an embodiment will be described, as an example, of the case where the controller 130 performs an operation of dynamically controlling one or more operating parameters corresponding to command operations when a data processing operation, particularly, command operations, are performed in the memory system 110. As described above, a processor 134 included in the controller 130 may perform the operation of dynamically controlling the operating parameters through, for example, an FTL, and a power management control module included in the controller 130.

Referring to FIG. 5, the controller 130 may receive from the host 102 a plurality of commands, for example, write commands, read commands, and/or erase commands and may perform along with the memory device 150 command operations corresponding to the received commands. The controller 130 may dynamically control one or more operating parameters for the command operations according to the job loads in the controller 130 and the memory device 150 which correspond to the command operations and the statuses of the controller 130 and the memory device 150 when the command operations are performed.

More specifically, the controller 130 parses, through a job parsing module 510, command jobs in the controller 130 and the memory device 150 according to their correspondence to the received commands and the command operations so that the command operations corresponding to the commands received from the host 102 are performed in the memory device 150. In other words, in the case where commands are provided from the host 102, a job parsing module 510 included in the controller 130 parses the command jobs in the controller 130 and the memory device 150 that correspond to the performing of the command operations so that the command operation corresponding to the commands are performed in the memory device 150. More specifically, the job parsing module 510 generates a command job list for the parsed command jobs. The job parsing module 510 fetches the commands received from the host 102 before parsing command jobs corresponding to the commands.

For example, the job parsing module 510 may parse program jobs for program operations in the controller 130 and the memory device 150 in response to write commands received from the host 102, and generate a program job list. The job parsing module 510 may parse read jobs for read operations in the controller 130 and the memory device 150 in response to read commands received from the host 102, and generate a read job list. The job parsing module 510 may parse erase jobs for erase operations in the controller 130 and the memory device 150 in response to erase commands, and generate an erase job list.

Furthermore, the controller 130 may then queue, through a sub-job queuing module 520, sub-operations for command operations corresponding to commands received from the host 102 such that the command operations corresponding to the commands received from the host 102 are performed in the memory device 150. In other words, the sub-job queuing module 520 checks and queues sub-jobs for the command jobs in the controller 130 and the memory device 150 that are parsed by the job parsing module 510 in correspondence with the commands and the command operations, as described above. The sub-job queuing module 520 checks the command job list generated in the job parsing module 510 and the command jobs parsed in the job parsing module 510 and then queues sub-jobs corresponding to the parsed command jobs. For example, the sub-job queuing module 520 queues sub-jobs on a logical unit size basis (for example, a unit size of 4 Kbits), and generates a sub-job list for the sub-jobs queued on a logical unit size basis in the sub-job queuing module 520. The sub-jobs queued in the sub-job queuing module 520 on a logical unit size basis are determined according to the number and size of commands, and the number and size of command operations corresponding to the commands.

For instance, the sub-job queuing module 520 may check program sub-jobs for program jobs through a program job list and the program jobs, queue the program sub-jobs on a logical unit size basis, and then generate a program sub-job list. The sub-job queuing module 520 may check read sub-jobs for read jobs through a read job list and the read jobs, queue the read sub-jobs on a logical unit size basis, and then generate a read sub-job list. The sub-job queuing module 520 may check erase sub-jobs for erase jobs through an erase job list and the erase jobs, queue the erase sub-jobs on a logical unit size basis, and then generate an erase sub-job list.

A plurality of sub-job modules 530 included in the controller 130 respectively perform, in a plurality of memory dies 610 to 695 included in the memory device 150, logical-unit-sized sub-jobs queued in the sub-job queuing module 520.

For example, the sub-job modules 530 may respectively perform, in the memory dies 610 to 695 of the memory device 150, logical-unit-sized program sub-jobs queued in the sub-job queuing module 520. The sub-job modules 530 respectively perform sub-jobs corresponding to data transmitting operations, data write operations, mapping operations, and map update operations for write data in program operations corresponding to write commands received from the host 102, as sub-operations for the program operations. For example, the sub-job modules 530 perform sub-jobs corresponding to operations of transmitting data from the host 102 to the controller 130 and operations of transmitting data from the controller 130 to corresponding memory blocks of the memory device 150, perform sub-jobs corresponding to operations of writing data in pages included in the corresponding memory blocks of the memory device 150, and perform sub-jobs associated with mapping operation and map update operations corresponding to the data write operations in the pages.

The sub-job modules 530 may respectively perform, in, the memory dies 610 to 695 of the memory device 150, logical-unit-sized read sub-jobs queued in the sub-job queuing module 520. The sub-job modules 530 may respectively perform sub-jobs corresponding to data transmitting operations, data sensing operations, map checking operations, and data decoding and error correction operations for read data in read operations corresponding to read commands received from the host 102, as sub-operations for the read operations. For example, the sub-job modules 530 perform sub-jobs corresponding to operations of transmitting data from the corresponding memory blocks of the memory device 150 to the controller 130 and operations of transmitting data from the controller 130 to the host 102, perform sub-jobs corresponding to data sensing operations in pages included in the corresponding memory blocks of the memory device 150, and perform sub-jobs corresponding to data decoding and error correction operations for data sensed in the data sensing operations.

The sub-job modules 530 may respectively perform, in the memory dies 610 to 695 of the memory device 150, logical-unit-sized erase sub-jobs queued in the sub-job queuing module 520. The sub-job modules 530 respectively perform sub-jobs corresponding to operations of checking the corresponding memory blocks, data erase operations, map update operations in erase operations corresponding to erase commands received from the host 102, as sub-operations for the erase operations. For example, the sub-job modules 530 perform sub-jobs corresponding to operations of checking the corresponding memory blocks associated with the erase commands, perform sub-jobs corresponding to data erase operations in the corresponding memory blocks, and perform sub-jobs corresponding to map update operations corresponding to the data erase operations.

As an example, parsing operations will be described in the case where the controller 130 performs command operations corresponding to commands received from the host 102, command jobs corresponding to the commands and the command operations, queuing sub-jobs, and performing the sub-jobs. However, it is noted, that even when the controller 130 performs background operations, for example, garbage collection operations or wear leveling operations, the controller 130 may parse a background job through the job parsing module 510, queue background sub-jobs through the sub-job queuing module 520, and perform background sub-jobs through the sub-job modules 530.

Furthermore, the controller 130 generates a reference clock of the memory system 110 through a generator 540, and performs along with the memory device 150 not only the command operations corresponding to the commands received from the host 102 using the reference clock but also the background operations or the like. In an exemplary embodiment, description will be made for the case where the generator 540 for generating a reference clock of the memory system 110 is present in the controller 130. However it is noted that in a modified embodiment, the generator 540 may be positioned independently outside the controller 130 and provide a reference clock to the memory system 110.

When performing not only the command operations corresponding to the commands received from the host 102 but also background operations, the controller 130 may monitor a temperature in the controller 130 and the memory device 150 through a monitor 1 550. The monitor 1 550 may include a temperature sensor and monitor an internal temperature of the controller 130 and the memory device 150 through the temperature sensor. In an embodiment, the monitor 1 550 may include at least two temperature sensors one for the controller 130 and one for the memory device 150. For instance, in the case where the controller 130 performs, in the respective memory dies 610 to 695 of the memory device 150, logical-unit-sized sub-jobs queued in the sub-job queuing module 520, the monitor 1 550 may monitor both of the temperature in the controller 130 and in the memory device 150.

The controller 130 may monitor performances and latencies in the controller 130 and the memory device 150 through monitor 2 560 included in the controller 130. For instance, in the case where the controller 130 performs, in the respective memory dies 610 to 695 of the memory device 150, logical-unit-sued sub-jobs queued in the sub-job queuing module 520, the monitor 2 560 monitors the performances and latencies in the controller 130 and the memory device 150.

A PMC module 570 checks the job loads in the controller 130 and the memory device 150 through the command jobs and a command job list in the job parsing module 510 and the sub-jobs and the sub-job list in the sub-job queuing module 520. In this regard, the PMC module 570 may calculate, through the command jobs, the command job list, the sub-jobs and the sub-job list, entire energy consumption needed when the sub-job modules 530 perform, in the respective memory dies 610 to 695 of the memory device 150, logical-unit-sized erase sub-jobs queued in the sub-job queuing module 520. In order to minimize the energy consumption, the PMC module 570 interactively and dynamically controls energy levels and operating clocks of the sub-job modules 530.

More specifically, the PMC module 570 may check the statuses of the controller 130 and the memory device 150 by periodically checking a temperature monitoring flag in the monitor 1 550 and performance and latency monitoring flags in the monitor 2 560. The PMC module 570, may then, based on the statuses of the controller 130 and the memory device 150, dynamically control, the operating parameters used when the sub-job modules 530 perform, in the respective memory dies 610 to 695 of the memory device 150, the logical-unit-sized sub-jobs which are queued in the sub-job queuing module 520.

For instance, when the sub-job modules 530 perform, in the respective memory dies 610 to 695 of the memory device 150, particular sub-jobs among logical-unit-sized sub-jobs queued in the sub-job queuing module 520, the temperatures in the controller 130 and the memory device 150 are monitored through the monitor 1 550, and the performances and latencies of the controller 130 and the memory device 150 for the arbitrary sub-jobs are monitored through the monitor 2 560. The PMC motor 570 checks the statuses of the controller 130 and the memory device 150 through the temperatures, performances and latencies of the controller 130 and the memory device 150. Furthermore, the PMC module 570 checks pending sub-jobs, other than the operation-completed sub-jobs among the logical-unit-sized sub-jobs queued in the sub-job queuing module 520, as job loads in the controller 130 and the memory device 150.

Furthermore, in correspondence with the statuses and the job loads in the controller 130 and the memory device 150, the PMC module 570 dynamically controls operating parameters used when the sub-job modules 530 perform, in the memory dies 610 to 695 of the memory device 150, the pending sub-jobs among the logical-unit-sized sub-jobs queued in the sub-job queuing module 520.

For example, in correspondence with the statuses and the job loads in the controller 130 and the memory device 150 the PMC module 570 dynamically controls, with reference to a reference clock generated by generator 540 included in the controller 130, operating clocks used when the sub-job modules 530 perform the respective pending sub-jobs. Here, the PMC module 570 dynamically controls the operating clocks by scaling up or down from the minimum clock to the maximum clock with reference to the reference clock generated by the generator 540.

Furthermore, in correspondence with the statuses and the job loads in the controller 130 and the memory device 150, the PMC module 570 dynamically controls an operating energy level (for example, levels of power, voltage or current provided from the interior or exterior of the memory system 110) when the sub-job modules 530 perform the respective pending sub-jobs. In this regard, the PMC module 570 may dynamically control, through scaling up or down an operating energy level (for example, an operating power level, an operating voltage level, or an operating current level) with reference to full energy levels (e.g., full power levels, full voltage levels, or full current levels) available for the memory system 110.

Here, the PMC module 570 dynamically controls operating clocks for the respective sub-job modules 530 which perform the corresponding logical-unit-sized sub-jobs. According to the operating clocks of the respective sub-job modules 530, the PMC module 570 also dynamically controls operating energy levels of the respective sub-job modules 530, thus making each sub-job module 530 have the maximum operating performance in the optimum power consumption level. In this regard, the PMC module 570 checks sub-jobs, in other words, job loads, to be performed in the respective memory dies 610 to 695 of the memory device 150, and the temperatures, performances and latencies, in other words, the statuses, of the respective sub-job modules 530 which perform the corresponding sub-jobs, and dynamically controls an operating clock and an operating energy level in the case where the sub-job modules 530 perform the corresponding sub-jobs in the respective memory dies 610 to 695.

For example, with regard to a command job parsed in the job parsing module 510, when sub-jobs that are currently performed among sub-jobs queued to the sub-job queuing module 520 are the last sub-jobs, the PMC module 570 controls the operating clocks of the corresponding sub-job modules 530 to the minimum clock through the scale down, and controls energy levels of the sub-job modules 530 through the scaling up or down according to the minimum clock.

Furthermore, with regard to a command job parsed in the job parsing module 510, for bottleneck sub-jobs in the case where of sub-jobs having the minimum performance and the maximum latency, that is, all sub-jobs corresponding to the command job, among the sub-jobs queued to the sub-job queuing module 520, are performed through monitoring using the monitor 2 560, the PMC module 570 controls operating energy levels of the corresponding sub-job modules 530 to the maximum energy level through scaling up, and controls operating clocks of the sub-job modules 530 to the maximum clock through scaling up according to the maximum energy level. In addition, with regard to a command job parsed in the job parsing module 510, for sub-jobs required to have the maximum performance among sub-jobs queued in the sub-job queuing module 520, the PMC module 570 controls operating energy levels of the corresponding sub-job modules 530 of the maximum-performance requiring sub-jobs to the maximum energy level through scaling up, and controls operating clocks of the sub-job modules 530 to the maximum performance clock through scaling up according to the maximum energy level.

With regard to a command job parsed in the job parsing module 510, in the case where the performances and the latencies of the sub-job modules 530 corresponding to sub-jobs queued in the sub-job queuing module 520 are maintained in the same statuses for a predetermined time, the PMC module 570 controls operating energy levels of the sub-job modules 530 through scaling down, and controls operating clocks of the sub-job modules 530 through scaling up at a point of time at which the operating energy levels of the sub-job modules 530 are maintained in a stable status.

In addition, with regard to a command job parsed in the job parsing module 510, for sub-jobs that have temperatures equal to or greater than a threshold temperature, which is checked through the monitor 1 550 among sub-jobs queued in the sub-job queuing module 520, the PMC module 570 controls operating energy levels and operating clocks of the corresponding sub-job modules 530 through scaling down. In the case where the temperatures of the sub-jobs become lower than the threshold temperature, the PMC module 570 controls the operating energy levels of the sub-job modules 530 through scaling up, and then controls the operating clocks of the sub-job modules 530 through scaling up at a point of time at which the operating energy levels are maintained in a normal status. The threshold temperature is set according to a set command, e.g., a set parameter command or a set picture command.

With regard to a command job parsed in the job paring module 510, for sub-jobs requiring specific performances, latencies and bandwidths among sub-jobs queued in the sub-job queuing module 520, the PMC module 570 dynamically controls operating energy levels and operating clocks of the corresponding sub-job modules 530 according to the specific performance, performance and latency.

In the described embodiment, description is focused on controlling operating parameters for a parsed command job and queued sub-jobs in correspondence with commands and command operations when the controller 130 performs the command operations corresponding to the commands. However, it is noted that when performing background operations, for example, garbage collection operations or wear leveling operations, the controller 130 may also dynamically control operating parameters for parsed ground jobs and queued background sub-jobs, through the PMC module 570.

Furthermore, the memory device 150 may include a plurality of memory dies, for example, N memory dies 610 to 695. Each of the memory dies 610 to 695 may perform not only command operations corresponding to commands received from the controller 130 but also background operations.

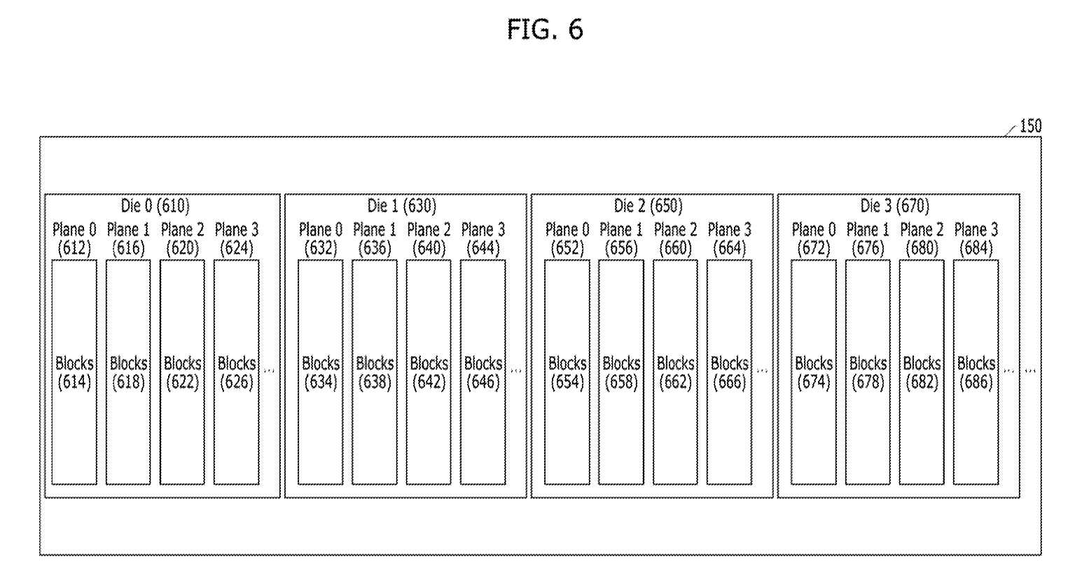

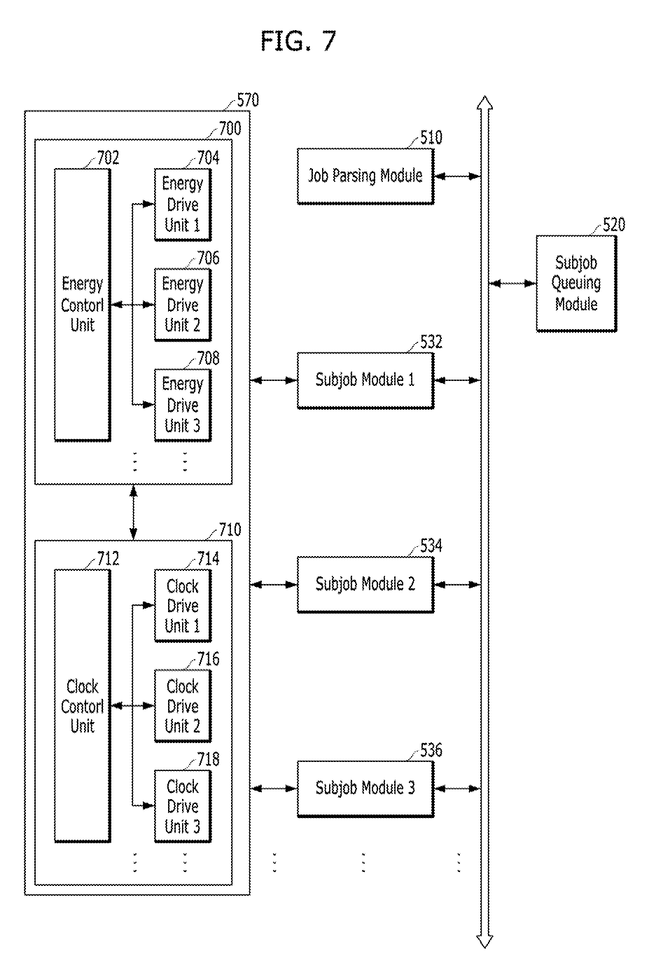

For instance, referring to FIG. 6, the memory device 150 includes a plurality of memory dies, for example, memory die 0 610, memory die 1 630, memory die 2 650, and memory die 3 670. Each of the memory dies 610, 630, 650 and 670 includes a plurality of planes. For example, the memory die 0 610 includes plane 0 612, plane 1 616, plane 2 620, and plane 3 624, the memory die 1 630 includes plane 0 632, plane 1 636, plane 2 640, and plane 3 644, the memory die 2 650 includes plane 0 652, plane 1 656, plane 2 660, and plane 3 664, and the memory die 3 670 includes plane 0 672, plane 1 676, plane 2 680, and plane 3 684. Each of the planes 612, 616, 620, 624, 632, 636, 640, 644, 652, 656, 660, 664, 672, 676, 680 and 684 of the memory dies 610, 630, 650 and 670 included in the memory device 150 includes a plurality of memory blocks 614, 618, 622, 626, 634, 638, 642, 646, 654, 658, 662, 666, 674, 678, 682, 686, for example, as described with reference to FIG. 2, N blocks Block0, Block 1, . . . , Block N-1 including a plurality of pages, e.g., 2M pages. Hereinafter, detailed description will be made with reference to FIG. 7 for an example of an operation of controlling operating parameters in the case where the memory device 150 of the memory system in accordance with an embodiment performs command operations corresponding to commands received from the host 102 or background operations. Furthermore, in an embodiment, for the sake of convenience in explanation, description will be made for an example of the operation of controlling operation parameters in the case where three arbitrary dies among a plurality of memory dies included in the memory device 150 receive read commands and write commands from the host 102 and perform read operations and program operations. In an embodiment, although there will be described in detail the operation of controlling the operating parameters, for example, controlling operating clocks and operating energy levels, in the case the memory dies included in the memory device 150 perform read operations and program operations, the like description may be applied to the operations of performing not only erase operations but also background operations, for example, garbage collection operations or wear leveling operations.

Referring to FIG. 7, when receiving read commands or write commands from the host 102, the controller 130 performs read operations corresponding to the read commands or program operations corresponding to the write commands, in a plurality of memory dies, e.g., memory die 0 610, memory die 1 630, and memory die 2 650, included in the memory device 150. Here, as described above, the controller 130 parses read jobs corresponding to the read commands and the read operations through the job parsing module 510, queues logical-unit-sized sub-jobs for the read jobs parsed in the job parsing module 510 through the sub-job queuing module 520, and perform the logical-unit-sized sub-jobs queued in the sub-job queuing module 520, in memory die 0 610, memory die 1 630, and memory die 2 650 of the memory device 150 through the sub-job modules 530, e.g., sub-job module 1 532, sub-job module 2 534, sub-job module 3 536. Furthermore, the controller 130 dynamically control, through the PMC module 570, operating parameters in the case where the logical-unit-sized sub-jobs queued in the sub-job queuing module 520 are performed through sub-job module 1 532, sub-job module 2 534, sub-job module 3 536. Particularly the controller 130 dynamically controls operating energy levels and operating clocks through an energy management control module 700 and a clock management control module 710 included in the PMC module 570.

In an embodiment, for the sake of convenience in explanation, there will be described in detail an example of an operation of controlling operating parameters in the case where the controller 130 receives read commands from the host 102 and performs read command operations in memory die 0 610, memory die 1 630 and memory die 2 650 of the memory device 150 and then there will be described in detail an example of an operation of controlling operating parameters in the case where the controller 130 receives write commands from the host 102 and performs program operations in memory die 0 610, memory die 1 630, and memory die 2 650 of the memory device 150. However, the like description may be applied to the case where the controller 130 receives different commands from the host 102 and independently and simultaneously performs corresponding command operations, for example, read operations, program operations and erase operations.

First, there will be described in detail an example of the case where, after receiving read commands from the host 102, the controller 130 performs read operations corresponding to the read commands in memory die 0 610, memory die 1 630, and memory die 2 650 of the memory device 150. The job parsing module 510 of the controller 130 parses read jobs for the read operations in the controller 130 and the memory device 150 in response to the read commands, and generates a read job list for the parsed read jobs. In this regard, the job parsing module 510 parses the read jobs that are performed in memory die 0 610, memory die 1 630, and memory die 2 650 through the read commands.

The sub-job queuing module 520 of the controller 130 checks read sub-jobs for the parsed read jobs, queues the read sub-jobs on a logical unit size basis, and generates a read sub-job list for the queued read sub-jobs. Here, the logical-unit-sized read sub-jobs are sub-operations to be included in the read operations.

For example, the logical-unit-sized read sub-jobs include first to third read operations in memory die 0 610, second read operations in memory die 1 630, and third read operations in memory die 2 650. Furthermore, the logical-unit-sized read sub-jobs include first data transmitting operations in the first read operations, second data transmitting operations in the second read operations, third data transmitting operations in the third read operations, first data sensing operations in the first read operations, second data sensing operations in the second read operations, third data sensing operations in the third read operations, first data decoding and error correction operations in the first read operations, second data decoding and error correction operations in the second read operations and third data decoding and error correction operations in the third read operations. In addition, the logical-unit-sized read sub-jobs include data transmitting operations in ail the memory dies 610 to 695, data sensing operations in all the memory dies 610 to 695, and data decoding and error correction operations in the all the memory dies 610 to 695.

The sub-job modules 532, 534, and 536 of the controller 130 may respectively perform, in the memory dies 610, 630, and 650 of the memory device 150, the logical-unit-sized read sub-jobs queued in the sub-job queuing module 520. Here, the sub-job modules 532, 534, and 536 respectively perform, in the corresponding memory dies 610, 630, and 650, the associated sub-jobs among the sub-jobs included in the read operations corresponding to the read commands.

For example, sub-job module 1 532 performs, among the logical-unit-sized read sub-jobs queued in the sub-job queuing module 520, first read operations in memory die 0 610, performs first data transmitting operations, second data transmitting operations, third data transmitting operations in the corresponding memory dies 610, 630, and 650, or performs data transmitting operations in all the memory dies 610 to 695. Furthermore, sub-job module 2 534 performs, among the logical-unit-sized read sub-jobs queued in the sub-job queuing module 520, second read operations in memory die 1 630, performs first data sensing operations, second data sensing operations, third data sensing operations in the corresponding memory dies 610, 630, and 650, or performs data sensing operations in the all memory dies 610, 630, . . . , 695. For example, sub-job module 3 536 performs, among the logical-unit-sized read sub-jobs queued in the sub-job queuing module 520 third read operations in memory die 2 650, performs first data decoding and error correction operations, second data decoding and error correction operations, third data decoding and error correction operations in the corresponding memory dies 610, 630, and 650, or performs data decoding and error correction operations in the all memory dies 610, 630, . . . , 695.

In this regard, monitor 1 550 of the controller 130 monitors internal temperatures of the controller 130 and the memory device 150 through the temperature sensors, as described above. Particularly, monitor 1 550 monitors the temperatures when the sub-job modules 532, 534, and 536 perform, in the respective memory dies 610, 630, and 650 of the memory device 150, logical-unit-sized read sub-jobs queued in the sub-job queuing module 520. A temperature monitoring flag corresponding to the monitored temperatures is transmitted to the PMC module 570. Furthermore, monitor 2 560 of the controller 130 monitors the performances and latencies when the sub-job modules 532, 534, and 536 perform, in the respective memory dies of the memory device 150, logical-unit-sized read sub-jobs queued in the sub-job queuing module 520. Performance and latency monitoring flags corresponding to the monitored performance and latency are transmitted to the PMC module 570.

That is, the PMC module 570 of the controller 130 checks the statuses, e.g., the temperatures, performances and latencies, of the controller 130 and the memory device 150 by periodically checking the temperature monitoring flag in the monitor 1 550 and the performance and latency monitoring flags in the monitor 2 560. Particularly, the PMC module 570 checks the temperatures, performances and latencies of the controller 130 and the memory device 150 when the sub-job modules 532, 534, and 536 perform, in the respective memory dies of the memory device 150, logical-unit-sized read sub-jobs queued in the sub-job queuing module 520. Furthermore, the PMC module 570 checks read jobs parsed in the job parsing module 510 and logical-unit-sized read sub-jobs queued in the sub-job queuing module 520, in other words, checks job loads of the controller 130 and the memory device 150. Particularly, the PMC module 570 not only checks logical-unit-sized read sub-jobs queued in the sub-job queuing module 520 but also checks pending read sub-jobs of the sub-job queuing module 520 as job loads of the controller 130 and the memory device 150 after performing particular read sub-jobs in the sub-job modules 532, 534, and 536.

For example, the PMC module 570 checks, through monitor 2 560, the performances and the latencies of read jobs parsed in the job parsing module 510, and checks not only logical-unit-sized read sub-jobs queued in the sub-job queuing module 520 but also pending read sub-jobs. Furthermore, the PMC module 570 checks, through monitor 2 560, the performances and latencies when the sub-job modules 532, 534 and 536 perform the corresponding read sub-jobs in the corresponding memory dies, respectively, for example, the performances and latencies when sub-job module 1 532 performs the corresponding read sub-jobs, the performances and latencies when sub-job module 2 534 performs the corresponding read sub-jobs, and the performances and latencies when sub-job module 3 536 performs the corresponding read sub-jobs. Here, the PMC module 570 checks pending read sub-jobs to be performed in sub-job module 1 532, pending read sub-jobs to be performed in sub-job module 2 534, and pending read sub-jobs to be performed in sub-job module 3 536. Furthermore, the PMC module 570 checks, through monitor 2 560, the performances and latencies at a point of time when the performing of the read jobs parsed in the job parsing module 510 is completed. Furthermore, the PMC module 570 checks, through monitor 1 550, the temperatures when the sub-job modules 532, 534 and 536 perform the corresponding read sub-jobs in the memory dies 610, 630, and 650, respectively, for example, the temperatures when sub-job module 1 532 performs the corresponding read sub-jobs, the temperatures when sub-job module 2 534 performs the corresponding read sub-jobs, and the temperatures when sub-job module 3 536 performs the corresponding read sub-jobs.

As such, the PMC module 570 checks the temperatures, latencies and performances when the sub-job modules 532, 534, and 536 respectively perform the corresponding read sub-jobs in the corresponding memory dies 610, 630, and 650, and checks pending read sub-jobs in the sub-job queuing module 520, particularly, pending read sub-jobs to be performed in the respective sub-job modules 532, 534, and 536, and thereafter dynamically controls the operating parameters, in other words, the operating energy levels and the operating clocks when the sub-job modules 532, 534, and 536 respectively perform the pending read sub-jobs in the corresponding memory dies 610, 630, and 650. Here, the PMC module 570 interactively and dynamically controls the operating energy levels and operating clocks of the sub-job modifies 532, 534, and 536.

In more detail, the PMC module 570 includes an energy management control module 700 which dynamically controls the respective operating energy levels of the sub-job modules 532, 534, and 536, and a clock management control module 710 which dynamically control the respective operating clocks of the sub-job modules 532, 534, and 536. The energy management control module 700 includes an energy control unit 702 which dynamically controls the respective operating energy levels of the sub-job modules 532, 534, and 536 according to the temperatures, performances, and latencies of the sub-job modules 532, 534, and 536, and pending read sub-jobs, and energy drive units 704, 706, and 708 which provide operating energy having the operating energy levels dynamically controlled by the energy control unit 702 to the respective sub-job modules 532, 534, and 536.

The energy management control module 700 includes energy drive unit 1 704 which scales up or down an operating energy level of sub-job module 1 532 and provides it to sub-job module 1 532 according to control of the energy control unit 702, energy drive unit 2 706 which scales up or down an operating energy level of sub-job module 2 534 and provides it to sub-job module 2 534 according to control of the energy control unit 702, and energy drive unit 3 708 which scales up or down an operating energy level of sub-job module 3 536 and provides it to sub-job module 3 538 according to control of the energy control unit 702. Furthermore, the energy management control module 700 dynamically controls operating energy levels by the respective sub-job modules 532, 534, and 536 from the all energy levels, e.g., the all power levels, the all voltage levels, or the all current levels, which can be used in the memory system 110. Here, the energy management control module 700 dynamically controls the operating energy levels while interacting with operating clocks in the sub-job modules 532, 534, and 536 that are controlled by the clock management control module 710.

The clock management control module 710 includes an clock control unit 712 which dynamically controls the respective operating clocks of the sub-job modules 532, 534, and 536 according to the temperatures, performances, and latencies of the sub-job modules 532, 534, and 536, and pending read sub-jobs, and clock drive units 714, 716, and 718 which provide the operating clocks dynamically controlled in the clock control unit 712, to the respective sub-job modules 532, 534, and 536.

The clock management control module 710 includes clock drive unit 1 714 which scales up or down an operating clock of sub-job module 1 532 and provides it to sub-job module 1 532 according to control of the clock control unit 712, clock drive unit 2 716 which scales up or down an operating clock of sub-job module 2 534 and provides it to sub-job module 2 534 according to control of the clock control unit 714, and clock drive unit 3 718 which scales up or down an operating clock of sub-job module 3 536 and provides it to sub-job module 3 538 according to control of the clock control unit 712. Furthermore, the clock management control module 710 dynamically controls operating clocks by the respective sub-job modules 532, 534, and 536 from the minimum clock to the maximum clock based on a reference clock generated by the generator 540. Here, the clock management control module 710 dynamically controls the operating clocks while interacting with operating energy levels in the sub-job modules 532, 534, and 536 that are controlled by the energy management control module 700.

For example, the clock management control module 710 controls the operating clocks of the sub-job modules 532, 534, and 536 to the minimum clock through scaling down when the sub-job modules 532, 534, and 536 perform third data transmitting operations, third data sensing operations and third data decoding and error correction operations as the last read sub-jobs of the pending read sub-jobs of the third read operations that are the last read operations. In addition, the energy management control module 700 controls the energy levels of the sub-job modules 532, 534, and 536 through scaling up or down in interaction with the minimum clock.

For example, the energy management control module 700 controls the operating energy level of sub-job module 3 536 to the maximum energy level through scaling up when sub-job module 3 536 performs first data decoding and error correction operations, second data decoding and error correction operations, third data decoding and error correction operations as read sub-jobs having the minimum performance and maximum latency among the pending read sub-jobs, in other words, as bottle neck read sub-jobs when all read sub-jobs corresponding to the read jobs are performed. In addition, the clock management control module 710 controls the operating clock of sub-job module 3 536 to the maximum clock through scaling up in Interaction with the maximum energy level.

For example, the energy management control module 700 controls the operating energy level of sub-job module 1 532 to the maximum energy level through scaling up when sub-job module 1 532 performs the first read operations as sub-jobs required to have the maximum performance among the pending read sub-jobs. In addition, the clock manage control module 710 controls the operating clock of sub-job module 1 532 to the maximum performance clock through scaling up in interaction with the maximum energy level.

In the case where the performance and latency of sub-job module 2 534 that performs the second read operations of the pending read sub-jobs are maintained in the same status for a predetermined time, the energy management control module 700 controls the operating energy level of sub-job module 2 534 through scaling down. In interaction with operating energy level control of the energy management control module 700, the clock management control module 710 controls the operating clock of sub-job module 2 534 through scaling up at a point of time at which the operating energy level of sub-job module 2 534 is maintained in a stable status.

For example, in the case where the temperature monitored by monitor 1 550 is the threshold temperature or more while the sub-job modules 532, 534, and 536 perform the queued read sub-jobs, the energy management control module 700 and the clock management control module 710 control, through scaling down, the operating energy level and the operating clock of sub-job module that performs read sub-jobs having temperatures equal to or greater than the threshold temperature.

For example, in the case where the temperature monitored by monitor 1 550 is less than the threshold temperature, the energy management control module 700 and the clock management control module 710 control, through scaling up, the operating energy level of sub-job module that performs read sub-jobs having temperatures less than the threshold temperature and then control the operating clock of the sub-job module through scaling up at a point of time at which the temperature is maintained in a normal status.

Furthermore, the energy manage control module 700 and the clock management control module 710 dynamically control, according to required performance, latency and bandwidth, the operating energy level and operating clock of sub-job module that performs first data transmitting operations, second data transmitting operations and third data transmitting operations as read sub-jobs having the required performance, latency and bandwidth among the pending read sub-jobs.

Next, there will be described in detail an example of the case where, after receiving write commands from the host 102, the controller 130 performs program operations corresponding to the write commands in memory die 0 610, memory die 1 630, and memory die 2 650 of the memory device 150. The job parsing module 510 of the controller 130 parses program jobs corresponding to the performing of the program operations in the controller 130 and the memory device 150 in correspondence with the write commands received from the host 102, and generates a program job list. In this regard, the job parsing module 510 parses the program jobs that the program operations are performed in memory die 0 610, memory die 1 620, and memory die 2 630 through the write commands.

The sub-job queuing module 520 of the controller 130 may then check the program sub-jobs which correspond to the program jobs parsed in the job parsing module 510, queues the program sub-jobs on a logical unit size basis, and generates a program sub-job list for the program sub-jobs queued on a logical unit size basis. The logical-unit-sized program sub-jobs queued in the sub-job queuing module 520 become sub-operations to be included in the program operations corresponding to the write commands received from the host 102.

For example, the logical-unit-sized program sub-jobs may include first program operations memory die 0 610, second program operations in memory die 1 620, and third program operations in memory die 2 630. Furthermore, the logical-unit-sized program sub-jobs may include first data transmitting operations in the first program operations, second data transmitting operations in the second program operations, third data transmitting operations in the third program operations, first data write operations in the first program operations, second data write operations in the second program operations third data write operations in the third program operations, first map update operations, in the first program operations, second map update operations in the second program operations, and third map update operations in the third program operations. In addition, the logical-unit-sized program sub-jobs may include data transmitting operations in the all memory dies 610, 630, . . . , 695, data write operations in the all memory dies 610, 630, . . . , 695, and map update operations in the all memory dies 610, 630, . . . , 695.

The sub-job modules 532, 534, and 536 of the controller 130 may respectively perform, in the memory dies 610, 630, and 650 of the memory device 150, the logical-unit-sized program sub-jobs queued in the sub-job queuing module 520. Here the sub-job modules 532, 534, and 536 respectively perform, in the corresponding memory dies 610, 630, and 650, the associated sub-jobs among the sub-jobs included in the program operations corresponding to the write commands received from the host 102.

For example, sub-job module 1 532 performs, among the logical-unit-sized program sub-jobs queued in the sub-job queuing module 520, first program operations in memory die 0 610, performs first data transmitting operations, second data transmitting operations, third data transmitting operations in the corresponding memory dies 610, 630, and 650, or performs data transmitting operations in the all memory dies 610, 630, . . . , 695. Furthermore, sub-job module 2 534 performs, among the logical-unit-sized program sub-jobs queued in the sub-job queuing module 520, second program operations in memory die 1 630, performs first data write operations, second data write operations, third data write operations in the corresponding memory dies 610, 630, and 650, or performs data write operations in the all memory dies 610, 630, . . . , 695. For example, sub-job module 3 536 performs, among the logical-unit-sized program sub-jobs queued in the sub-job queuing module 520, third program operations in memory die 2 650, performs first map update operations, second map update operations, third map update operations in the corresponding memory dies 610, 630, and 650, or performs map update operations in all the memory dies 610, 630, . . . , 695.

In this regard, monitor 1 550 of the controller 130 monitors internal temperatures of the controller 130 and the memory device 150 through the temperature sensors, as described above. Particularly, monitor 1 550 monitors the temperatures when the sub-job modules 532, 534, and 536 perform, in the respective memory dies 610, 630, and 650 of the memory device 150, logical-unit-sized program sub-jobs queued in the sub-job queuing module 520. A temperature monitoring flag corresponding to the monitored temperatures is transmitted to the PMC module 570. Furthermore, monitor 2 560 of the controller 130 monitors the performance and latency when the sub-job modules 532, 534, and 536 perform, in the respective memory dies 610, 630, and 650 of the memory device 150, the logical-unit-sized program sub-jobs queued in the sub-job queuing module 520, as described above. Performance and latency monitoring flags corresponding to the monitored performance and latency are transmitted to the PMC module 570.

That is, the PMC module 570 of the controller 130 checks the statuses, e.g., the temperatures, performances and latencies, of the controller 130 and the memory device 150 by periodically checking the temperature monitoring flag in the monitor 1 550 and the performance and latency monitoring flags in the monitor 2 560. Particularly, the PMC module 570 checks the temperatures, performances and latencies of the controller 130 and the memory device 150 when the sub-job modules 532, 534 and 536 perform, in the respective memory dies 610, 630, and 650 of the memory device 150, logical-unit-sized program sub-jobs queued in the sub-job queuing module 520. Furthermore, the PMC module 570 checks program jobs parsed in the job parsing module 510 and logical-unit-sized program sub-jobs queued in the sub-job queuing module 520, in other words, checks job loads of the controller 130 and the memory device 150. Particularly, the PMC module 570 not only checks logical-unit-sized program sub-jobs queued to the sub-job queuing module 520 but also checks remaining program sub-jobs, that is, pending read sub-jobs, of the sub-job queuing module 520 as job loads of the controller 130 and the memory device 150 after performing program sub-jobs in the sub-job modules 532, 534, and 536.

For example, the PMC module 570 checks, through monitor 2 560 the performances and the latencies of program jobs parsed in the job parsing module 510, and checks not only logical-unit-sized program sub-jobs queued in the sub-job queuing module 520 but also remaining logical-unit-sized program sub-jobs, that is, pending program sub-jobs. Furthermore, the PMC module 570 checks, through monitor 2 560, the performances and latencies in the case where the sub-job modules 532, 534 and 536 perform the corresponding program sub-jobs in the memory dies 610, 630, and 650, respectively, for example, the performances and latencies when sub-job module 1 532 performs the corresponding program sub-jobs, the performances and latencies of program sub-jobs when sub-job module 2 534 performs the corresponding program sub-jobs, and the performances and latencies of program sub-jobs when sub-job module 3 536 performs the corresponding program sub-jobs. Here, the PMC module 570 checks pending program sub-jobs to be performed in sub-job module 1 532, pending program sub-jobs to be performed in sub-job module 2 534, and pending program sub-jobs to be performed in sub-job module 3 536. Furthermore, the PMC module 570 checks, through monitor 2 560, the performances and latencies at a point of time when the performing of the program jobs parsed in the job parsing module 510 is completed. Furthermore, the PMC module 570 checks, through monitor 1 550, the temperatures when the sub-job modules 532, 534 and 536 perform the corresponding program sub-jobs in the memory dies 610, 630, and 650, respectively, for example, the temperatures when sub-job module 1 532 performs the corresponding program sub-jobs, the temperatures when sub-job module 2 534 performs the corresponding program sub-jobs, and the temperatures when sub-job module 3 536 performs the corresponding program sub-jobs.

As such, the PMC module 570 checks the temperatures, latencies and performances when the sub-job modules 532, 534, and 536 respectively perform the corresponding program sub-jobs in the memory dies 610, 630, and 650, and checks remaining program sub-jobs (that is, pending program sub-jobs) in the sub-job queuing module 520, particularly, pending program sub-jobs to be performed in the respective sub-job modules 532, 534, and 536, and thereafter dynamically controls the operating parameters, in other words, the operating energy levels and the operating clocks when the sub-job modules 532, 534, and 536 respectively perform the pending program sub-jobs in the memory dies 610, 630, and 650. Here, the PMC module 570 interactively and dynamically controls the operating energy levels and operating clocks of the sub-job modules 532, 534, and 536.

Particularly, as described above, the PMC module 570 includes an energy management control module 700 which dynamically controls the respective operating energy levels of the sub-job modules 532, 534, and 536, and a clock management control module 710 which dynamically control the respective operating clocks of the sub-job modules 532 534, and 536. Here, the energy management control module 700 dynamically controls the operating energy levels in interaction with the operating clocks of the sub-job modules 532, 534, and 536 that are controlled by the clock management control module 710. The clock management control module 710 dynamically control the operating clocks in interaction with the operating energy levels of the sub-job modules 532, 534, and 536 that are controlled by the energy management control module 700.

The energy management control module 700 includes an energy control unit 702 which dynamically controls the respective operating energy levels of the sub-job modules 532, 534, and 536 in correspondence with the temperatures, performances, and latencies of the sub-job modules 532, 534, and 536, and pending program sub-jobs, and energy drive units 704, 706, and 708 which provide operating energy having the operating energy levels dynamically controlled in the energy control unit 702, to the respective sub-job modules 532, 534, and 536. In this regard, the energy control unit 702 and the energy drive units 704, 706, and 708 of the energy management control module 700 have been described in detail; therefore, further description thereof will be omitted. Furthermore, the energy management control module 700 dynamically controls operating energy levels by the respective sub-job modules 532, 534, and 536 among the all energy levels, the all power levels, the all voltage levels, or the all current levels, which can be used in the memory system 110.

The clock management control module 710 includes an clock control unit 712 which dynamically controls the respective operating clocks of the sub-job modules 532, 534, and 536 in correspondence with the temperatures, performances, and latencies of the sub-job modules 532, 534, and 536, and pending program sub-jobs, and clock drive units 714, 716, and 718 which provide the operating clocks dynamically controlled in the clock control unit 712, to the respective sub-job modules 532, 534, and 536. In this regard, the clock control unit 712 and the clock drive units 714, 716, and 718 of the clock management control module 710 have been described in detail; therefore, further description thereof will be omitted. Furthermore, the clock management control module 710 dynamically controls operating clocks by the respective sub-job modules 532, 534, and 536 from the minimum clock to the maximum clock in correspondence with a reference clock generated by the generator 540.

For example, the clock management control module 710 controls the operating clocks of the sub-job modules 532, 534, and 536 to the minimum clock through scaling down when the sub-job modules 532, 534, and 536 perform third data transmitting operations, third write operations, and third map update operations of the third program operations that are the last program operations, as the last program sub-jobs of the pending program sub-jobs. In addition, the energy management control module 700 controls the energy levels of the sub-job modules 532, 534, and 536 through scaling up or down, in interaction with the minimum clock. Furthermore, the energy management control module 700 controls the operating energy level of sub-job module 3 536 to the maximum energy level through scaling up when sub-job module 3 536 performs first map update operations, second map update operations, third map update operations as program sub-jobs having the minimum performance and maximum latency among the pending program sub-jobs, in other words, as bottle neck program sub-jobs when all program sub-jobs corresponding to the program jobs are performed. The clock management control module 710 controls the operating clock of sub-job module 3 536 to the maximum clock through scaling up, in interaction with the maximum energy level. In addition, the energy management control module 700 controls the operating energy level of sub-job module 1 532 to the maximum energy level through scaling up when sub-job module 1 532 performs the first program operations as sub-jobs needed to have the maximum performance among the pending program sub-jobs. The clock manage control module 710 controls the operating clock of sub-job module 1 532 to the maximum performance clock through scaling up, in interaction with the maximum energy level.

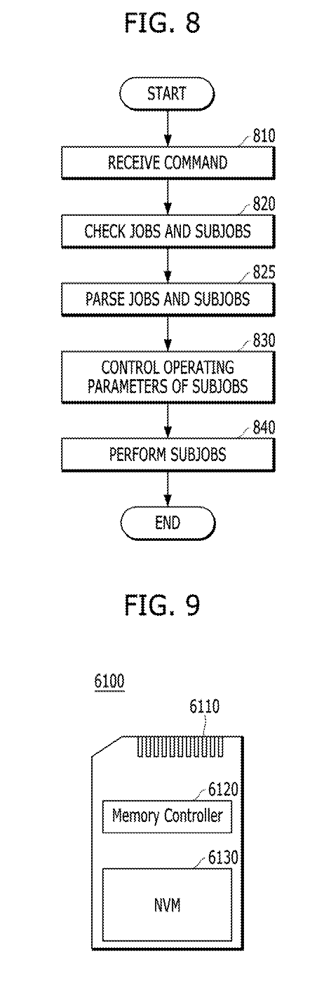

In the case where the performance and latency of sub-job module 2 534 that performs the second program operations of the pending program sub-jobs are maintained in the same status for a predetermined time, the energy management control module 700 controls the operating energy level of sub-job module 2 534 through scaling down. In interaction with operating energy level control of the energy management control module 700, the clock management control module 710 controls the operating clock of sub-job module 2 534 through scaling up at a point of time at which the operating energy level of sub-job module 2 534 is maintained in a stable status. In addition in the case where the temperature monitored by monitor 1 550 is the threshold temperature or more while the sub-job modules 532, 534, and 536 perform the queued program sub-jobs, the energy management control module 700 and the clock management control module 710 control, through scaling down, the operating energy level and the operating clock of sub-job module 3 536 that performs program sub-jobs having temperatures equal to or greater than the threshold temperature. In the case where the temperature monitored by monitor 1 550 is less than the threshold temperature, the energy management control module 700 and the clock management control module 710 control the operating energy level of sub-job module 3 536 through scaling up, and then control the operating clock of sub-job module 3 536 through scaling up at a point of time at which the temperature is maintained in a normal status. Furthermore, the energy manage control module 700 and the clock management control module 710 dynamically control, according to required performance, latency and bandwidth, the operating energy level and operating clock of sub-job module 1 532 that performs first data transmitting operations second data transmitting operations and third data transmitting operations as program sub-jobs having the required performance, latency and bandwidth among the pending program sub-jobs. As such, in the memory system in accordance with an embodiment, in the case where command operations for commands received from the host 102 are performed, command jobs of the controller 130 and the memory device 150 corresponding to the command operations are parsed, and then sub-jobs corresponding to the command jobs are queued according to a logical unit size basis. In the case where the logical-unit-sized sub-jobs are performed, job loads (e.g., queuing and pending sub-jobs), in the controller 130 and the memory device 150, and statuses, (e.g., temperatures, performance, and latencies) in the controller 130 and the memory device 150 are monitored in real time. According to the job loads and statuses of the controller 130 and the memory device 150 that are monitored in real time, the operating energy levels and the operating clocks of the sub-job modules 530 that perform the logical-unit-sized sub-jobs are dynamically controlled. Particularly, the memory system in accordance with an embodiment dynamically controls the operating energy level and the operating clock in interaction with each other to have the maximum performance and the minimum latency below the threshold temperature in consideration of all the energy levels and the maximum clock that can be used in the memory system. Hereinbelow, detailed description will be made, with reference to FIG. 8, for the operation of controlling the operating parameter in the case where the memory system in accordance with an embodiment performs a command operation.

FIG. 8 is a flowchart illustrating an operation of a memory system, in accordance with an embodiment of the present invention. The memory system may be the memory system 110 as described in FIGS. 1-7.

Referring to FIG. 8, the memory system 110 receives commands for the memory device 150 from the host 102, at step 810. The memory device 150 may include a plurality of memory dies 610 to 695 and the received commands may be for one or more of the memory dies 610 to 695.At step 820, the memory system 110 checks command jobs in the controller 130 and the memory device 150 corresponding to command operations of the commands received from the host 102, and also sub-jobs corresponding to the command jobs. The controller 130 may then parse the command jobs corresponding to the command operations, and queue the sub-jobs corresponding to the parsed command jobs on a logical unit size basis.

Thereafter, at step 830, the memory system 110 interactively and dynamically controls the operating parameters, e.g., operating energy levels and operating clocks, when the queued logical-unit-sized sub-jobs are performed in the memory dies of the memory device 150. For example, the memory system 110 monitors job loads (e.g., pending sub-jobs and queued logical-unit-sized sub-jobs,) in the controller 130 and the memory device 150, and the statuses in the controller 130 and the memory device 150. The statuses may be, for example, the temperatures, performances and latencies of the controller 130 and the memory device 150 that perform the sub-jobs. Subsequently, the memory system dynamically controls the operating parameters (e.g., the energy level and the operating clock) when performing the sub-jobs according to the job loads and the statuses of the controller 130 and the memory device 150.

At step 840, the memory system performs the queued logical-unit-sized sub-jobs with the operating parameters (e.g., the operating energy level and the operating clock) that are dynamically controlled at step 830.

A detailed description has been provided with reference to FIGS. 5 to 7, for the operation of controlling the operating parameter in the memory system 110 when performing the command operations corresponding to commands received from the host 102, for example, the operation of checking the job loads and the statuses of the controller 130 and the memory device 150 of the memory system 110 and then interactively and dynamically controlling the operating energy level and the operating clock when performing the command operations of the controller 130 and the memory device 150. Therefore, further description thereof will be omitted.

Hereinafter, various embodiments of the present invention including the memory system 110 described with reference to FIGS. 1 to 8 will be described in more detail with reference to FIGS. 9 to 17.

FIGS. 9 to 17 are diagrams schematically illustrating application examples of the data processing system of FIG. 1.

FIG. 9 is a diagram schematically illustrating another example of the data processing system 100. FIG. 9 schematically illustrates a memory card system to which the memory system in accordance with the present embodiment is applied.

Referring to FIG. 9, the memory card system 6100 may include a memory controller 6120, a memory device 6130 and a connector 6110.

More specifically, the memory controller 6120 may be connected to the memory device 6130 embodied by a nonvolatile memory, and configured to access the memory device 6130. For example, the memory controller 6120 may be configured to control read, write, erase and background operations of the memory device 6130. The memory controller 6120 may be configured to provide an interface between the memory device 6130 and a host, and drive firmware for controlling the memory device 6130. That is, the memory controller 6120 may correspond to the controller 130 of the memory system 110 described with reference to FIGS. 1 and 5, and the memory device 6130 may correspond to the memory device 150 of the memory system 110 described with reference to FIGS. 1 and 5.

Thus, the memory controller 6120 may include a RAM, a processing unit, a host interface a memory interface and an error correction unit. The memory controller 130 may further include the elements shown in FIG. 5.

The memory controller 6120 may communicate with an external device, for example, the host 102 of FIG. 1 through the connector 6110. For example, as described with reference to FIG. 1, the memory controller 6120 may be configured to communicate with an external device through one or more of various communication protocols such as universal serial bus (USB) multimedia card (MMC), embedded MMC (eMMC), peripheral component interconnection (PCI), PCI express (PCIe), Advanced Technology Attachment (ATA), Serial-ATA, Parallel-ATA, small computer system interface (SCSI), enhanced small disk interface (EDSI), Integrated Drive Electronics (IDE), Firewire, universal flash storage (UFS), WIFI and Bluetooth. Thus, the memory system and the data processing system in accordance with the present embodiment may be applied to wired/wireless electronic devices or particularly mobile electronic devices.

The memory device 6130 may be implemented by a nonvolatile memory. For example, the memory device 6130 may be implemented by various nonvolatile memory devices such as an erasable and programmable ROM (EPROM), an electrically erasable and Programmable ROM (EEPROM), a NAND flash memory, a NOR flash memory, a phase-change RAM (PRAM), a resistive RAM (ReRAM) a ferroelectric RAM (FRAM) and a spin torque transfer magnetic RAM (STT-RAM). The memory device 6130 may include a plurality of dies as in the memory device 150 of FIG. 5.

The memory controller 6120 and the memory device 6130 may be integrated into a single semiconductor device. For example, the memory controller 6120 and the memory device 6130 may construct a solid state driver (SSD) by being integrated into a single semiconductor device. Also, the memory controller 6120 and the memory device 6130 may construct a memory card such as a PC card (PCMCIA: Personal Computer Memory Card International Association), a compact flash (CF) card, a smart media card (e.g., SM and SMC), a memory stick, a multimedia card (e.g., MMC, RS-MMC, MMCmicro and eMMC), an SD card (e.g., SD, miniSD, microSD and SDHC) and a universal flash storage (UFS).

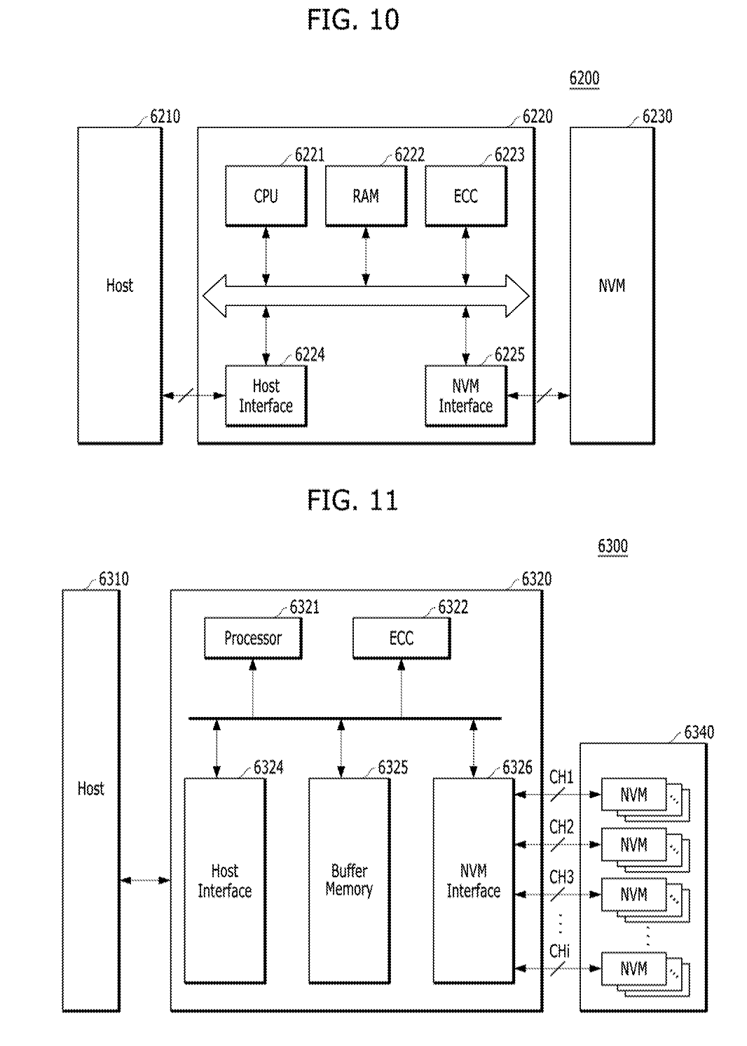

FIG. 10 is a diagram schematically illustrating another example of the data processing system including the memory system in accordance with an embodiment.

Referring to FIG. 10, the data processing system 6200 may include a memory device 6230 having one or more nonvolatile memories and a memory controller 6220 for controlling the memory device 6230. The data processing system 6200 illustrated in FIG. 10 may serve as a storage medium such as a memory card (CF, SD, micro-SD or the like) or USB device, as described with reference to FIG. 1. The memory device 6230 may correspond to the memory device 150 in the memory system 110 illustrated in FIGS. 1 and 5, and the memory controller 6220 may correspond to the controller 130 in the memory system 110 illustrated in FIGS. 1 and 5.

The memory controller 6220 may control a read, write or erase operation on the memory device 6230 in response to a request of the host 6210, and the memory controller 6220 may include one or more CPUs 6221, a buffer memory such as RAM 6222, an ECC circuit 6223, a host interface 6224 and a memory interface such as an NVM interface 6225.

The CPU 6221 may control overall operations on the memory device 6230, for example, read, write, file system management and bad page management operations. The RAM 6222 may be operated according to control of the CPU 6221, and used as a work memory, buffer memory or cache memory. When the RAM 6222 is used as a work memory, data processed by the CPU 6221 may be temporarily stored in the RAM 6222. When the RAM 6222 is used as a buffer memory, the RAM 6222 may be used for buffering data transmitted to the memory device 6230 from the host 6210 or transmitted to the host 6210 from the memory device 6230. When the RAM 6222 is used as a cache memory, the RAM 6222 may assist the low-speed memory device 6230 to operate at high speed.

The ECC circuit 6223 may correspond to the ECC unit 138 of the controller 130 illustrated in FIG. 1. As described with reference to FIG. 1, the ECC circuit 6223 may generate an ECC (Error Correction Code) for correcting a fail bit or error bit of data provided from the memory device 6230. The ECC circuit 6223 may perform error correction encoding on data provided to the memory device 6230, thereby forming data with a parity bit. The parity bit may be stored in the memory device 6230. The ECC circuit 6223 may perform error correction decoding on data outputted from the memory device 6230. At this time, the ECC circuit 6223 may correct an error using the parity bit. For example, as described with reference to FIG. 1, the ECC circuit 6223 may correct an error using the LDPC code, BCH code, turbo code, Reed-Solomon code, convolution code, RSC or coded modulation such as TCM or BCM.

The memory controller 6220 may transmit/receive data to/from the host 6210 through the host interface 6224, and transmit/receive data to/from the memory device 6230 through the NVM interface 6225. The host interface 6224 may be connected to the host 6210 through a PATA bus, SATA bus, SCSI, USB, PCIe or NAND interface. The memory controller 6220 may have a wireless communication function with a mobile communication protocol such as WiFi or Long Term Evolution (LTE). The memory controller 6220 may be connected to an external device, for example, the host 6210 or another external device and then transmit/receive data to/from the external device. In particular as the memory controller 6220 is configured to communicate with the external device through one or more of various communication protocols, the memory system, and the data processing system in accordance with the present embodiment may be applied to wired/wireless electronic devices or particularly a mobile electronic device.

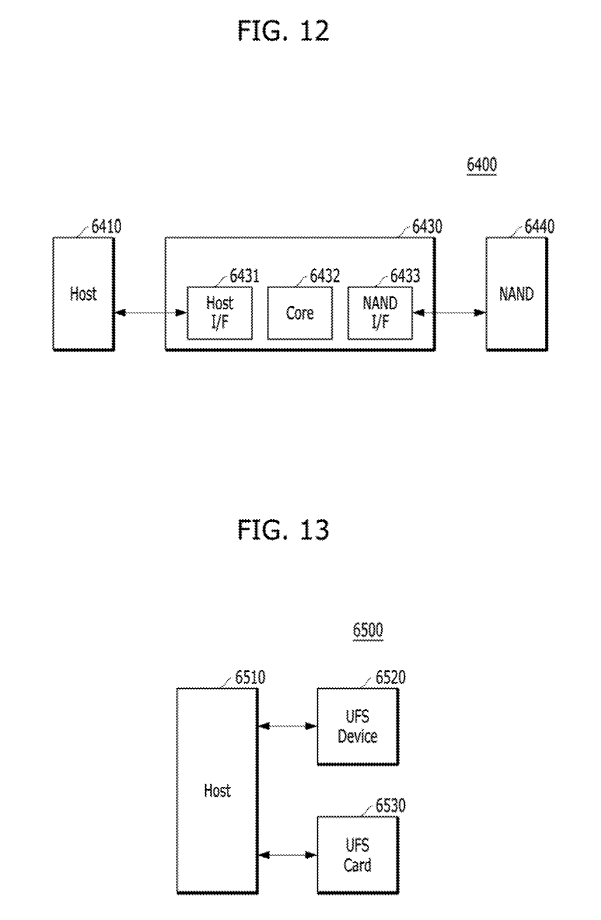

FIG. 11 is a diagram schematically illustrating another example of the data processing system including the memory system in accordance with an embodiment. FIG. 12 schematically illustrates an SSD including the memory system 110.

Referring to FIG. 11, the SSD 6300 may include a controller 6320 and a memory device 6340 including a plurality of nonvolatile memories. The controller 6320 may correspond to the controller 130 in the memory system 110 of FIGS. 1 and 5, and the memory device 6340 may correspond to the memory device 150 in the memory system of FIGS. 1 and 5.

More specifically, the controller 6320 may be connected to the memory device 6340 through a plurality of channels CH1 to CHi. The controller 6320 may include one or more processors 6321, a buffer memory 6325, an ECC circuit 6322, a host interface 6324 and a memory interface, for example, a nonvolatile memory interface 6326.

The buffer memory 6325 may temporarily store data provided from the host 6310 or data provided from a plurality of flash memories NVM included in the memory device 6340 or temporarily store meta data of the plurality of flash memories NVM, for example, map data including a mapping table. The buffer memory 6325 may be embodied by volatile memories such as DRAM, SDRAM, DDR SDRAM, LPDDR SDRAM and GRAM or nonvolatile memories such as FRAM, ReRAM, STT-MRAM and PRAM. For convenience of description, FIG. 10 illustrates that the buffer memory 6325 exists in the controller 6320. However, the buffer memory 6325 may exist outside the controller 6320.

The ECC circuit 6322 may calculate an ECC value of data to be programmed to the memory device 6340 during a program operation, perform an error correction operation on data read from the memory device 6340 based on the ECC value during a read operation, and perform an error correction operation on data recovered from the memory device 6340 during a failed data recovery operation.

The host interface 6324 may provide an interface function with an external device, for example, the host 6310, and the nonvolatile memory interface 6326 may provide an interface function with the memory device 6340 connected through the plurality of channels.

Furthermore, a plurality of SSDs 6300 to which the memory system 110 of FIGS. 1 and 5 is applied may be provided to embody a data processing system, for example, RAID (Redundant Array of Independent Disks) system. At this time, the RAID system may include the plurality of SSDs 6300 and a RAID controller for controlling the plurality of SSDs 6300. When the RAID controller performs a program operation in response to a write command provided from the host 6310, the RAID controller may select one or more memory systems or SSDs 6300 according to a plurality of RAID levels, that is, RAID level information of the write command provided from the host 6310 in the SSDs 6300, and output data corresponding to the write command to the selected SSDs 6300. Furthermore, when the RAID controller performs a read command in response to a read command provided from the host 6310, the RAID controller may select one or more memory systems or SSDs 6300 according to a plurality of RAID levels, that is, RAID level information of the read command provided from the host 6310 in the SSDs 6300, and provide data read from the selected SSDs 6300 to the host 6310.

FIG. 12 is a diagram schematically illustrating another example of the data processing system including the memory system in accordance with an embodiment. FIG. 13 schematically illustrates an embedded Multi-Media Card (eMMC) including the memory system 110.

Referring to FIG. 12, the eMMC 6400 may include a controller 6430 and a memory device 6440 embodied by one or more NAND flash memories. The controller 6430 may correspond to the controller 130 in the memory system 110 of FIGS. 1 and 5, and the memory device 6440 may correspond to the memory device 150 in the memory system 110 of FIGS. 1 and 5.

More specifically, the controller 6430 may be connected to the memory device 6440 through a plurality of channels. The controller 6430 may include one or more cores 6432, a host interface 6431 and a memory interface, for example, a NAND interface 6433.

The core 6432 may control overall operations of the eMMC 6400, the host interface 6431 may provide an interface function between the controller 6430 and the host 6410, and the NAND interface 6433 may provide an interface function between the memory device 6440 and the controller 6430. For example, the host interface 6431 may serve as a parallel interface, for example, MMC interface as described with reference to FIG. 1. Furthermore, the host interface 6431 may serve as a serial interface, for example, UHS ((Ultra High Speed)-I/UHS-II) interface.

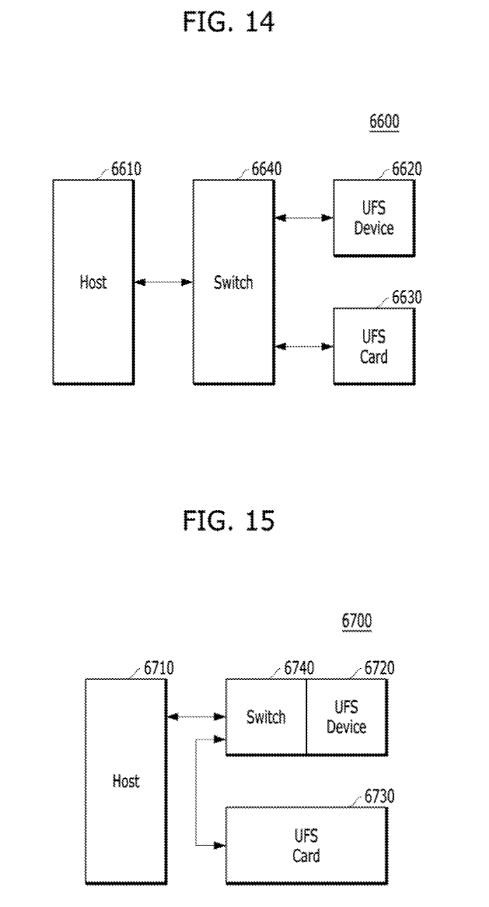

FIGS. 13 to 16 are diagrams schematically illustrating other examples of the data processing system including the memory system in accordance with an embodiment. Specifically, FIGS. 14 to 17 schematically illustrate Universal Flash Storage (UFS) systems including the memory system 110.

Referring to FIGS. 13 to 16, the UFS systems 6500, 6600, 6700 and 6800 may include hosts 6510, 6610, 6710 and 6810, UFS devices 6520, 6620, 6720 and 6820 and UFS cards 6530, 6630, 6730 and 6830, respectively. The hosts 6510, 6610, 6710 and 6810 may serve as application processors of wired/wireless electronic devices or particularly mobile electronic devices, the UFS devices 6520, 6620, 6720 and 6820 may serve as embedded UFS devices, and the UFS cards 6530, 6630, 6730 and 6830 may serve as external embedded UFS devices or removable UFS cards.

The hosts 6510, 6610, 6710 and 6810, the UFS devices 6520, 6620, 6720 and 6820 and the UFS cards 6530, 6630, 6730 and 6830 in the respective UFS systems 6500, 6600, 6700 and 6800 may communicate with external devices, for example, wired/wireless electronic devices or particularly mobile electronic devices through UFS protocols, and the UFS devices 6520, 6620, 6720 and 6820 and the UFS cards 6530, 6630, 6730 and 6830 may be embodied by the memory system 110 illustrated in FIGS. 1 and 5. For example, in the UFS systems 6500, 6600, 6700 and 6800, the UFS devices 6520, 6620, 6720 and 6820 may be embodied in the form of the data processing system 6200, the SSD 6300 or the eMMC 6400 described with reference to FIGS. 10 to 12, and the UFS cards 6530, 6630, 6730 and 6830 may be embodied in the form of the memory card system 6100 described with reference to FIG. 9.

Furthermore, in the UFS systems 6500, 6600, 6700 and 6800, the hosts 6510, 6610, 6710 and 6810, the UFS devices 6520, 6620, 6720 and 6820 and the UFS cards 6530, 6630, 6730 and 6830 may communicate with each other through an UFS interface, for example, MIPI M-PHY and MIDI Unified Protocol (UniPro) in Mobile Industry Processor Interface (MIPI). Furthermore, the UFS devices 6520, 6620, 6720 and 6820 and the UFS cards 6530, 6630, 6730 and 6830 may communicate with each other through various protocols other than the UFS protocol, for example, UFDs, MMC, SD, mini-SD, and micro-SD.

In the UFS system 6500 illustrated in FIG. 13, each of the host 6510, the UFS device 6520 and the UFS card 6530 may include UniPro. The host 6510 may perform a switching operation in order to communicate with the UFS device 6520 and the UFS card 6530. In particular, the host 6510 may communicate with the UFS device 6520 or the UFS card 6530 through link layer switching, for example, L3 switching at the UniPro. At this time, the UFS device 6520 and the UFS card 6530 may communicate with each other through link layer switching at the UniPro of the host 6510. In the present embodiment, the configuration in which one UFS device 6520 and one UFS card 6530 are connected to the host 6510 has been exemplified for convenience of description. However, a plurality of UFS devices and UFS cards may be connected in parallel or in the form of a star to the host 6410, and a plurality of UFS cards may be connected in parallel or in the form of a star to the UFS device 6520 or connected in series or in the form of a chain to the UFS device 6520.

In the UFS system 6600 illustrated in FIG. 14, each of the host 6610, the UFS device 6620 and the UFS card 6630 may include UniPro, and the host 6610 may communicate with the UFS device 6620 or the UFS card 6630 through a switching module 6640 performing a switching operation, for example, through the switching module 6640 which performs link layer switching at the UniPro, for example, L3 switching. The UFS device 6620 and the UFS card 6630 may communicate with each other through link layer switching of the switching module 6640 at UniPro. In the present embodiment, the configuration in which one UFS device 6620 and one UFS card 6630 are connected to the switching module 6640 has been exemplified for convenience of description. However, a plurality of UFS devices and UFS cards may be connected in parallel or in the form of a star to the switching module 6640, and a plurality of UFS cards may be connected in series or in the form of a chain to the UFS device 6620.

In the UFS system 6700 illustrated in FIG. 15, each of the host 6710, the UFS device 6720 and the UFS card 6730 may include UniPro, and the host 6710 may communicate with the UFS device 6720 or the UFS card 6730 through a switching module 6740 performing a switching operation, for example, through the switching module 6740 which performs link layer switching at the UniPro, for example, L3 switching. At this time, the UFS device 6720 and the UFS card 6730 may communicate with each other through link layer switching of the switching module 6740 at the UniPro, and the switching module 6740 may be integrated as one module with the UFS device 6720 inside or outside the UFS device 6720. In the present embodiment, the configuration in which one UFS device 6720 and one UFS card 6730 are connected to the switching module 6740 has been exemplified for convenience of description. However, a plurality of modules each including the switching module 6740 and the UFS device 6720 may be connected in parallel or in the form of a star to the host 6710 or connected in series or in the form of a chain to each other. Furthermore a plurality of UFS cards may be connected in parallel or in the form of a star to the UFS device 6720.

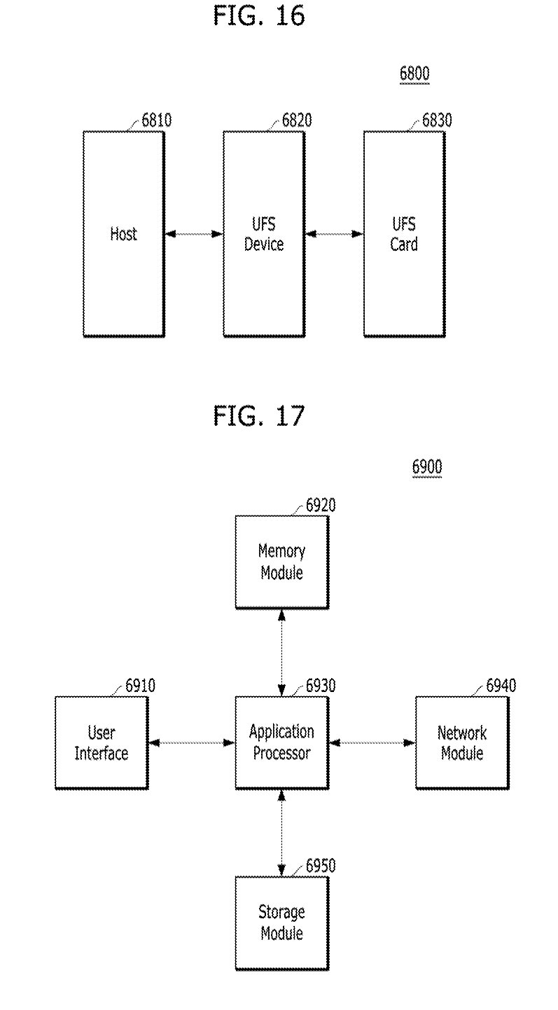

In the UFS system 6800 illustrated in FIG. 16, each of the host 6810, the UFS device 6820 and the UFS card 6830 may include M-PHY and UniPro. The UFS device 6820 may perform a switching operation in order to communicate with the host 6810 and the UFS card 6830. In particular, the UFS device 6820 may communicate with the host 6810 or the UFS card 6830 through a switching operation between the M-PHY and UniPro module for communication with the host 6810 and the M-PHY and UniPro module for communication with the UFS card 6830, for example, through a target ID (Identifier) switching operation. At this time, the host 6810 and the UFS card 6830 may communicate with each other through target ID switching between the M-PHY and UniPro modules of the UFS device 6820. In the present embodiment, the configuration in which one UFS device 6820 is connected to the host 6810 and one UFS card 6830 is connected to the UFS device 6820 has been exemplified for convenience of description. However, a plurality of UFS devices may be connected in parallel or in the form of a star to the host 6810, or connected in series or in the form of a chain to the host 6810, and a plurality of UFS cards may be connected in parallel or in the form of a star to the UFS device 6820, or connected in series or in the form of a chain to the UFS device 6820.

FIG. 17 is a diagram schematically illustrating another example of the data processing system including a memory system in accordance with an embodiment. FIG. 18 is a diagram schematically illustrating a user system including the memory system 110.

Referring to FIG. 17 the user system 6900 may include an application processor 6930, a memory module 6920, a network module 6940, a storage module 6950 and a user interface 6910.

More specifically, the application processor 6930 may drive components included in the user system 6900, for example, an OS, and include controllers, interfaces and a graphic engine which control the components included in the user system 6900. The application processor 6930 may be provided as System-on-Chip (SoC).

The memory module 6920 may be used as a main memory, work memory, buffer memory or cache memory of the user system 6900. The memory module 6920 may include a volatile RAM such as DRAM, SDRAM, DDR SDRAM, DDR 2 SDRAM, DDR3 SDRAM, LPDDR SDARM, LPDDR3 SDRAM or LPDDR3 SDRAM or a nonvolatile RAM such as PRAM, ReRAM, MRAM or FRAM. For example, the application processor 6930 and the memory module 6920 may be packaged and mounted, based on POP (Package on Package).

The network module 6940 may communicate with external devices. For example, the network module 6940 may not only support wired communication, but also support various wireless communication protocols such as code division multiple access (CDMA), global system for mobile communication (GSM), wideband CDMA (WCDMA), CDMA-2000, time division multiple access (TDMA), long term evolution (LTE), worldwide interoperability for microwave access (Wimax), wireless local area network (WLAN), ultra-wideband (UWB), Bluetooth, wireless display (WI-DI) thereby communicating with wired/wireless electronic devices or particularly mobile electronic devices. Therefore, the memory system and the data processing system, in accordance with an embodiment of the present invention, can be applied to wired/wireless electronic devices. The network module 6940 may be included in the application processor 6930.

The storage module 6950 may store data, for example, data received from the application processor 6930, and then may transmit the stored data to the application processor 6930. The storage module 6950 may be embodied by a nonvolatile semiconductor memory device such as a phase-change RAM (PRAM), a magnetic RAM (MRAM), a resistive RAM (ReRAM), a NAND flash, NOR flash and 3D NAND flash, and provided as a removable storage medium such as a memory card or external drive of the user system 6900. The storage module 6950 may correspond to the memory system 110 described with reference to FIGS. 1 and 5. Furthermore, the storage module 6950 may be embodied as an SSD, eMMC and UFS as described above with reference to FIGS. 11 to 16.

The user interface 6910 may include interfaces for inputting data or commands to the application processor 6930 or outputting data to an external device. For example, the user interface 6910 may include user input interfaces such as a keyboard, a keypad, a button, a touch panel, a touch screen, a touch pad, a touch ball a camera a microphone, a gyroscope sensor, a vibration sensor and a piezoelectric element, and user output interfaces such as a liquid crystal display (LCD), an organic light emitting diode (OLED) display device, an active matrix OLED (AMOLED) display device, an LED, a speaker and a motor.

Furthermore, when the memory system 110 of FIGS. 1 and 5 is applied to a mobile electronic device of the user system 6900, the application processor 6930 may control overall operations of the mobile electronic device, and the network module 6940 may serve as a communication module for controlling wired/wireless communication with an external device. The user interface 6910 may display data processed by the processor 6930 on a display/touch module of the mobile electronic device, or support a function of receiving data from the touch panel.

In a memory system and an operating method thereof in accordance with embodiments, it is possible to minimize the complexity and performance deterioration of the memory system and maximize efficiency in use of the memory device, thus making it possible to rapidly and reliably process data with respect to the memory device.

Although various embodiments have been described for illustrative purposes, it will be apparent to those skilled in the art that various other embodiments, changes and modifications thereof may be made without departing from the spirit and scope of the invention as defined in the following claims.

What is claimed is:

1. A memory system comprising:
a memory device including a plurality of memory dies and suitable for performing, in the plurality of memory dies, command operations; and
a controller suitable for:
dividing sub-jobs of a command job corresponding to the command operations on a logical unit size basis;
queuing the divided sub-jobs; and
performing the queued sub-jobs to the memory dies with variable operating energy levels and operating clocks,
wherein the controller monitors a status and a job load for at least one queued sub-job while performing the at least one queued sub-job to the memory dies and interactively and dynamically adjusts an energy level and an operating clock for the at least one queued sub-job according to a result of the monitoring.

2. The memory system of claim 1,
wherein the controller performs a plurality of first sub-jobs of the queuing sub-jobs in a first operating energy level and a first operating clock, and then performs pending first sub-jobs of the queuing sub-jobs in the third operating energy level and the third operating clock, and
wherein the controller performs and a plurality of second sub-jobs of the queuing sub-jobs in a second operating energy level and a second operating clock and then performs pending second sub-jobs of the queuing sub-jobs in a fourth operating energy level and a fourth operating clock.

3. The memory system of claim 2,
wherein the controller monitors a first status and a first job load corresponding to the performing of the first sub-jobs, in the first operating energy level and the first operating clock, and
wherein the controller monitors a second status and a second job load corresponding to the performing of the second sub-jobs, in the second operating energy level and the second operating clock.

4. The memory system of claim 3,
wherein the controller determines the third operating energy level and the third operating clock, through scale up or down for the first operating energy level and the first operating clock, in correspondence with the first status and the first job load, and
wherein the controller determines the fourth operating energy level and the fourth operating clock, through scale up or down for the second operating energy level and the second operating clock, in correspondence with the second status and the second job load.

5. The memory system of claim 4, wherein, in the case where the pending second sub-jobs are last sub-jobs of the queuing sub-jobs, the controller determines the fourth operating clock as a minimum clock, through scale down for the second operating clock, and then determines the fourth operating energy level, through scale up or down for the second operating energy level, in correspondence with the fourth operating clock that is the minimum clock.

6. The memory system of claim 1, wherein the controller controls one or more of energy level and operating clock for sub-jobs having a minimum performance and a maximum latency or sub-jobs requiring a maximum performance among the queued sub-jobs such that the energy level is a maximum energy level and the operating clock is a maximum operating clock.

7. The memory system of claim 1, wherein, in the case where a temperature in the memory device and the controller is equal to or greater than a threshold temperature, the controller scales down the energy level and the operating clock for the at least one queued sub-job.

8. The memory system of claim 1, wherein, in the case where a temperature in the memory device and the controller is lower than a threshold temperature, the controller scales up or down the energy and the operating clock for the at least one queued sub-job.

9. The memory system of claim 1, wherein, in the case where performance and latency of the at least one queued sub-job is maintained in the same status for a predetermined time, the controller scales down the energy level and scales up the operating clock for the at least one queued sub-job.

10. The memory system of claim 1,
wherein the status includes temperatures, performances and latencies of the controller and the memory device, and
wherein the job load includes pending sub-jobs of the queued sub-jobs.

11. The memory system of claim 1, wherein the controller comprises:
a job parsing module suitable for parsing the command job;
a sub-job queuing module suitable for queuing the sub-jobs corresponding to the parsed command job on the logical unit size basis;
sub-job modules suitable for respectively performing the queued sub-jobs to corresponding the memory dies;
a monitor suitable for monitoring temperatures, performances and latencies in the controller and the memory device while the sub-job modules respectively perform the queued sub-jobs; and
a power management control module suitable for checking monitoring flag for the parsed command job, the queued sub-jobs, the temperatures, the performances, and the latencies, and then adjusting one or more of the operating energy levels and the operating clocks of the respective sub-job modules.

12. The memory system of claim 11, wherein the power manage control module comprises:
control units suitable for controlling one or more of the operating energy levels and the operating clocks of the respective sub-job modules according to the parsed command job, the queued sub-jobs, and the monitoring flag; and
drive units suitable for providing the controlled operating energy levels and/or the controlled operating clocks to the respective sub-job modules.

13. A method for operating a memory system which includes a memory device including a plurality of memory dies, the method comprising:
dividing sub-jobs of a command job corresponding to the command operations on a logical unit size basis;
queuing the divided sub-jobs;
performing the queued sub-jobs to the memory dies with variable operating energy levels and operating clocks;
monitoring statuses and job loads of the queued sub-jobs during the performing of the queued sub-jobs; and
interactively and dynamically controlling one or more of the energy levels and the operating clocks through scale up or scale down according to a result of the monitoring,
wherein the statuses include temperatures, performances and latencies in the memory device and a controller of the memory device, and
wherein the job loads include pending sub-jobs of the queued sub-jobs.

14. The operating method of claim 13, wherein the performing comprises:
performing first sub-jobs of the queuing sub-jobs in a first operating energy level and a first operating clock, and then performing pending first sub-jobs of the queuing sub-jobs in a third operating energy level and a third operating clock; and
performing second sub-jobs of the queuing sub-jobs in a second operating energy level and a second operating clock, and then performing pending second sub-jobs of the queuing sub-jobs in a fourth operating energy level and a fourth operating clock, and
wherein the monitoring comprises:
monitoring a first status and a first job load corresponding to the performing of the first sub-jobs, in the first operating energy level and the first operating clock; and
monitoring a second status and a second job load corresponding to the performing of the second sub-jobs, in the second operating energy level and the second operating clock.

15. The operating method of claim 13, wherein the controlling comprises:
determining the third operating energy level and the third operating clock, through scale up or down for the first operating energy level and the first operating clock, in correspondence with the first status and the first job load; and
determining the fourth operating energy level and the fourth operating clock, through scale up or down for the second operating energy level and the second operating clock, in correspondence with the second status and the second job load.

16. The operating method of claim 13, wherein the controlling of one or more of the energy levels and the operating clocks includes controlling one or more of energy level and operating clock for last sub-jobs of the queued sub-jobs such that the operating clock is a minimum operating clock and the energy level corresponds to the minimum operating clock.

17. The operating method of claim 13, wherein the controlling of one or more of the energy levels and the operating clocks includes controlling one or more of energy level and operating clock for sub-jobs having a minimum performance and a maximum latency or sub-jobs requiring a maximum performance among the queued sub-jobs such that the energy level is a maximum energy level and the operating clock is a maximum operating clock.

18. The operating method of claim 13, wherein, in the case where temperatures in the memory device and the controller are equal to or greater than a threshold temperature, the controlling of one or more of the energy levels and the operating clocks includes scaling down one or more of the energy levels and the operating clocks for the queued sub-jobs.

19. The operating method of claim 13, wherein, in the case where the temperatures in the memory device and the controller are lower than the threshold temperature, the controlling of one or more of the energy levels and the operating clocks includes scaling up one or more of the energy levels and the operating clocks for the queued sub-jobs.

20. The operating method of claim 13, wherein, in the case where performance and latency of the first sub-jobs are maintained in the same statuses for a predetermined time, the controlling of one or more of the energy levels and the operating clocks includes scaling down the energy levels and scaling up the operating clocks for the queued sub-jobs.
